(19) United States
(12) Patent Application Publication
(10) Pub. No.: US 2015/0069349 A1
(43) Pub. Date: Mar. 12, 2015

(54) METHOD OF PREPARING ORGANIC ELECTROLUMINESCENT ELEMENT AND ORGANIC ELECTROLUMINESCENT ELEMENT

(71) Applicant: PANASONIC CORPORATION, Osaka (JP)

(72) Inventors: Shintaro Hayashi, Hyogo (JP); Kazuyuki Yamae, Nara (JP); Masuyuki Ota, Osaka (JP)

(73) Assignee: PANASONIC CORPORATION, Osaka (JP)

(21) Appl. No.: 14/381,633

(22) PCT Filed: Mar. 7, 2013
(86) PCT No.: PCT/JP2013/001472

§ 371 Date: Aug. 28, 2014

(30) Foreign Application Priority Data
Mar. 8, 2012 (JP) 2012-052181

(51) Int. Cl. H01L 51/56; H01L 51/52

(52) U.S. Cl. CPC H01L 51/56; H01L 51/5253
USPC 257/40; 438/26

(57) ABSTRACT

Provided is a method of preparing an organic electroluminescent element. The method includes: a roughening step of roughening a surface of a moisture-proof substrate; a composite substrate-forming step of placing a resin film on the roughened surface of the moisture-proof substrate to form a composite substrate; an electroluminescent laminate-forming step of forming an organic electroluminescent laminate on a surface of the composite substrate; and a covering step of covering the organic electroluminescent laminate with a covering substrate that is larger than the resin film in a plan view. It gives a highly reliable organic electroluminescent element superior in light-outcoupling efficiency that is effectively resistant to water penetration and to degradation.

### TECHNICAL FIELD

The present invention relates to methods for preparing an organic electroluminescent element and to organic electroluminescent elements.

### BACKGROUND ART

Recently, organic electroluminescent elements (hereinafter, referred to as “organic EL elements”) have been used in applications such as lighting panels. Organic EL elements including an optically transparent first electrode (anode), a multi-layered organic layer containing a light-emitting layer, and a second electrode (cathode) formed in that order on an optically transparent substrate are known. In organic EL elements, the light generated in the light-emitting layer by application of voltage between the anode and the cathode is transmitted outward though the optically transparent electrode and substrate.

### PRIOR ART DOCUMENTS

### Patent Literature

Patent Document 1: JP 2002-373777 A

### SUMMARY OF THE INVENTION

### Problems to be Resolved by the Invention

Generally in organic EL elements, the intensity of the light generated in the light-emitting layer is decreased for example by absorption in the substrate and total reflection at a layer interface and thus, the intensity of the light withdrawn outward is smaller than the theoretical light intensity. For example, when a glass is used as a material of the substrate, the glass, which normally has a refractive index lower than that of organic layer, causes total reflection of the light at the interface, leading to decrease of the light-outcoupling efficiency. Thus, there exist a demand for improvement in the light-outcoupling efficiency of organic EL elements for improvement in brightness. It may be possible for that purpose to use a high-refractive index glass in order to make the difference in refractive index smaller. However, such high-refractive index glasses have disadvantages that they are expensive and also brittle in physical properties. It is also known as another measure to install a plastic substrate between the electrode at a side where light is to emerge and the glass substrate for improvement in light-outcoupling efficiency (see, for example, Patent Document 1). It is possible by installing a plastic substrate to the light-outcoupling side to suppress the total reflection at the interface between the substrate and the electrode and to obtain the light emitted outward in a greater amount.

Since the light-emitting layer in organic EL elements is susceptible to degradation by water, it is important to prevent penetration of water into the element. Degradation of the light-emitting layer by water causes troubles such as insufficient light emission, leading to deterioration of the reliability of the organic EL element. Particularly when a relatively high water-permeability material such as a plastic material is used as the substrate for improvement of light-outcoupling efficiency, the material causes a problem of inward penetration of water through it.

In Patent Document 1, a laminate including a light-emitting layer is formed on a plastic substrate; then, the plastic substrate is adhered to a glass substrate and the entire substrate is covered. In this case, as the plastic substrate is enclosed by a moisture-proof substrate, penetration of water through the plastic substrate is suppressed. However, the method demands production of the element by formation of the laminate on a plastic substrate, which may make the production process complicated. In addition, when the plastic substrate carrying the laminate is adhered to a glass substrate, the resultant entire laminate becomes thicker, possibly prohibiting reduction in size of the final product.

An object of the present invention, which was made under the circumstances above, is to provide a highly reliable organic electroluminescent element that can be easily prepared and is superior in light-outcoupling efficiency and effectively resistant to water penetration and also to degradation.

### Means of Solving the Problems

The method of preparing an organic electroluminescent element according to the present invention includes characteristically a roughening step of roughening a surface of a moisture-proof substrate, a composite substrate-forming step of placing a resin film on the roughened surface of the moisture-proof substrate to form a composite substrate, an electroluminescent laminate-forming step of forming an organic electroluminescent laminate on a surface of the composite substrate, and a covering step of covering the organic electroluminescent laminate with a covering substrate that is larger than the resin film in a plan view.

Preferably, the method of preparing an organic electroluminescent element further includes a recess-forming step of forming a recess in the surface of the moisture-proof substrate by digging, and the composite substrate-forming step is carried out by fitting the resin film into the recess to form the composite substrate.

Preferably, in the method of preparing an organic electroluminescent element, the roughening step is carried out by providing the surface of the moisture-proof substrate with a protective member and roughening the surface.

Preferably, in the method of preparing an organic electroluminescent element, the surface is roughened by making particles collide with the surface of the moisture-proof substrate in the roughening step.

Preferably, in the method of preparing an organic electroluminescent element, the recess-forming step is carried out by making particles collide with the surface of the moisture-proof substrate to form the recess.

Preferably, in the method of preparing an organic electroluminescent element, the roughening step and the recess-forming step are carried out simultaneously.

The method of preparing an organic electroluminescent element preferably further includes an electrode layer-forming step of:

forming an electrode layer on the surface of the composite substrate after the composite substrate-forming step so that the electrode layer extends across a boundary between the resin film and the moisture-proof substrate; or

forming an electrode layer on a surface of the covering substrate before the covering step so that the electrode layer is to be electrically connected to an electrode of the organic electroluminescent laminate in the covering step.

Preferably, in the method of preparing an organic electroluminescent element, the electrode layer is formed by printing.

The organic electroluminescent element according to the present invention includes a composite substrate including a moisture-proof substrate and a resin film, the moisture-proof substrate having a roughened surface, and the resin film being placed on the roughened surface of the moisture-proof substrate; a covering substrate being larger than the resin film in a plan view; and an organic electroluminescent laminate formed on a surface of the resin film, the organic electroluminescent laminate being covered with the covering substrate.

Preferably, in the organic electroluminescent element, the resin film is embedded in the moisture-proof substrate.

The organic electroluminescent element preferably further includes an electrode layer,

the electrode layer being formed on a surface of the composite substrate so as to extend across a boundary between the moisture-proof substrate and the resin film, or
the electrode layer being formed on a surface of the covering substrate.

### Effect of the Invention

It is possible by the method of preparing an organic electroluminescent element according to the present invention to produce easily a highly reliable organic electroluminescent element that is superior in light-outcoupling efficiency and effectively resistant to water penetration and thus to degradation. It is possible according to the present invention to obtain a highly reliable organic electroluminescent element that is superior in light-outcoupling efficiency and effectively resistant to water penetration and thus to degradation.

### BRIEF DESCRIPTION OF DRAWINGS

FIGS. 1A and 1B show an embodiment of the organic electroluminescent element, wherein FIG. 1A is a cross-sectional view and FIG. 1B is a plan view.

FIG. 2 is an example of a production process for the composite substrate, wherein recesses are formed on a moisture-proof substrate.

FIG. 3A to 3G are cross-sectional views illustrating an example of the step of roughening a surface of the moisture-proof substrate.

FIG. 4A to 4F are cross-sectional views illustrating another example of the step of roughening the surface of the moisture-proof substrate.

FIG. 5 is an example of the production process for the composite substrate, wherein the moisture-proof substrate and the resin film are adhered to each other.

FIG. 6 is an example of the production process for the composite substrate, wherein electrode layers are formed.

FIG. 7A to 7F are plan views illustrating an example of the production process for the organic electroluminescent element.

FIG. 8A to 8C are cross-sectional views illustrating an example of the organic electroluminescent element.

FIG. 9 is a cross-sectional view illustrating an embodiment of the organic electroluminescent element.

FIG. 10 is a cross-sectional view illustrating an embodiment of the organic electroluminescent element.

FIGS. 11A to 11C are plan views illustrating an example of the production process for the organic electroluminescent element.

FIG. 12 is an example of the electrode layer-forming step.

FIG. 13 is a cross-sectional view illustrating an example of the organic electroluminescent element.

FIG. 14 is an example of the electrode layer-forming step.

FIG. 15 is a cross-sectional view illustrating an example of the organic electroluminescent element.

FIG. 16 is a cross-sectional view illustrating an example of the organic electroluminescent element.

FIG. 17 is a cross-sectional view illustrating a comparative example of the organic electroluminescent element.

### DESCRIPTION OF EMBODIMENTS

### Embodiment 1

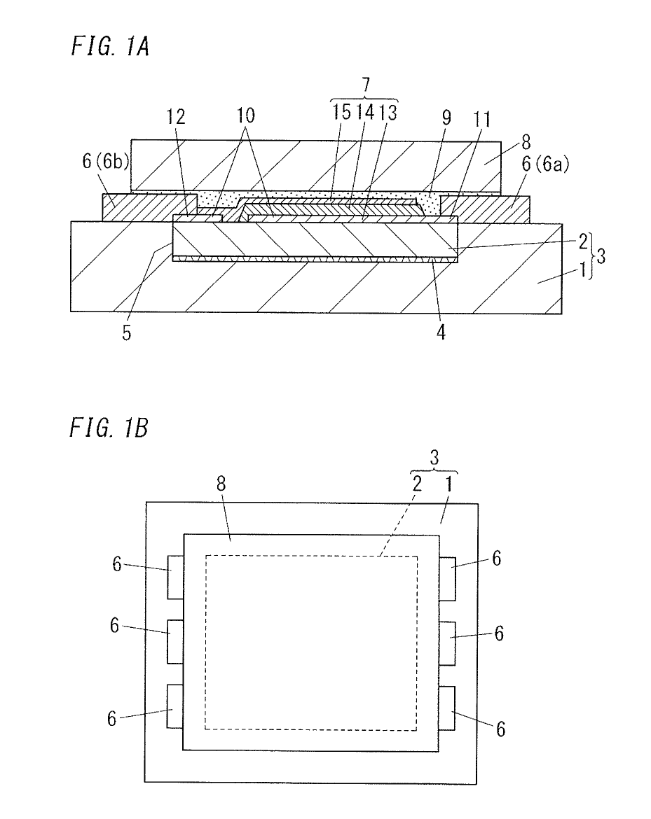

FIGS. 1A and 1B are views illustrating an embodiment of an organic electroluminescent element (organic EL element). In the organic EL element, a composite substrate 3 including a moisture-proof substrate 1 and a resin film 2 is used as a substrate for an organic electroluminescent laminate 7. An organic electroluminescent laminate 7 having a first electrode 13, an organic layer 14, and a second electrode 15 in this order is formed on the surface of the resin film 2 of the composite substrate 3. The organic electroluminescent laminate 7 is covered by a covering substrate 8 that is adhered to the composite substrate 3 with an adhesive sealing layer 9. The region between the composite substrate 3 and the covering substrate 8 is the covered region. An electrode layer 6 (first electrode layer 6a) electrically connected to the first electrode 13 and an electrode layer 6 (second electrode layer 6b) electrically connected to the second electrode 15 are formed, as they extend from outside into the covered region. The electrode layers 6 can serve as electrode terminals for connection to external electric wirings.

Regarding FIG. 1A, in order to briefly illustrate the structure of the element configuration, the end region on which the first electrode layer 6a is formed is shown in the right side and the end region on which the second electrode layer 6b is formed is shown in the left side. FIG. 1B is a view of the organic EL element when seen from the side of covering substrate 8, wherein the peripheral edge of the resin film 2 is indicated by a broken line to make the configuration of the substrate clearer.

In the organic EL element of FIGS. 1A and 1B, the resin film 2 is embedded in a recess of the moisture-proof substrate 1. A light-outcoupling structure 4 is formed at the interface between the moisture-proof substrate 1 and the resin film 2. The organic electroluminescent laminate 7 is covered with a covering substrate 8 larger than the resin film 2 in a plan view (when seen from the direction perpendicular to the surface of the composite substrate 3). The covering substrate 8 is adhered to the moisture-proof substrate 1 (composite substrate 3) directly without the resin film 2 in the end region. In FIG. 1A, both ends of the covering substrate 8 are located outside both ends of the resin film 2. Specifically in a plan view shown in FIG. 1B, the peripheral ends of the covering substrate 8 are located outside peripheral ends of the resin film 2 and the resin film 2 is covered with the covering substrate 8 larger than the resin film 2.

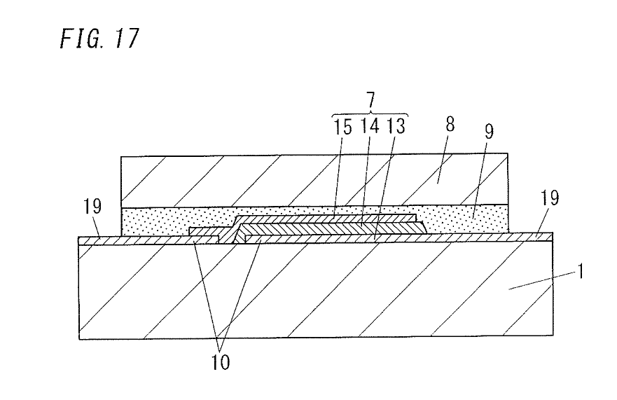

For comparison with the organic EL element in FIGS. 1A and 1B, a comparative example of the organic EL element is shown in FIG. 17. In the organic EL element, an organic electroluminescent laminate 7 having a first electrode 13, an organic layer 14 containing a light-emitting layer, and a second electrode 15 in that order is formed on the surface of a moisture-proof substrate 1 such as an optically transparent glass substrate. The organic electroluminescent laminate 7 is covered with a covering substrate 8 by adhesion with an adhesive sealing layer 9 and thus isolated from the external environment. There are formed electrode terminals 19 that are electrically connected to the first electrode 13 and the second electrode 15 in the region outside the covered region. The first electrode 13 and the electrode terminals 19 are formed, as the optically transparent electroconductive layer 10 is formed in a patterned shape.

In such an organic EL element shown in FIG. 17, a composite substrate of glass and plastic may be used as the substrate material, instead of the moisture-proof substrate 1, for improvement of the light-outcoupling efficiency. However in such a case, water may penetrate inward via the plastic region easily.

Alternatively in the organic EL element shown in FIGS. 1A and 1B, the resin film 2 is not exposed to the external environment and thus penetration of water can be suppressed effectively.

### [Preparation of Organic EL Element]

A method for preparing an organic EL element shown in FIGS. 1A and 1B will be described below.

The organic EL element in the present embodiment is prepared in a process including a recess-forming step, a roughening step, a composite substrate-forming step, an electroluminescent laminate-forming step and a covering step. The recess-forming step is a step of forming a recess 5 by digging the surface of the moisture-proof substrate 1. The roughening step is a step of roughening the surface of the moisture-proof substrate 1. The composite substrate-forming step is a step of forming a composite substrate 3 by forming a resin film 2 on the surface of the moisture-proof substrate 1. The electroluminescent laminate-forming step is a step of forming an organic electroluminescent laminate 7 on the surface of the composite substrate 3. The covering step is a step of covering the organic electroluminescent laminate 7 with a covering substrate 8 larger than the resin film 2 in a plan view.

In the present embodiment, the composite substrate 3 is prepared by fitting a resin film 2 into the recess 5 in the composite substrate-forming step. When a molded article is used as the resin film 2, the composite substrate 3 can be prepared by placing the resin film 2 in the recess 5 and adhering it to the moisture-proof substrate 1.

The method of preparing the organic EL element in the present embodiment further includes an electrode layer-forming step. The electrode layer-forming step in the present embodiment is a step of forming an electrode layer 6 on the surface of the composite substrate 3 after the composite substrate-forming step across the boundary region between the resin film 2 and the moisture-proof substrate 1.

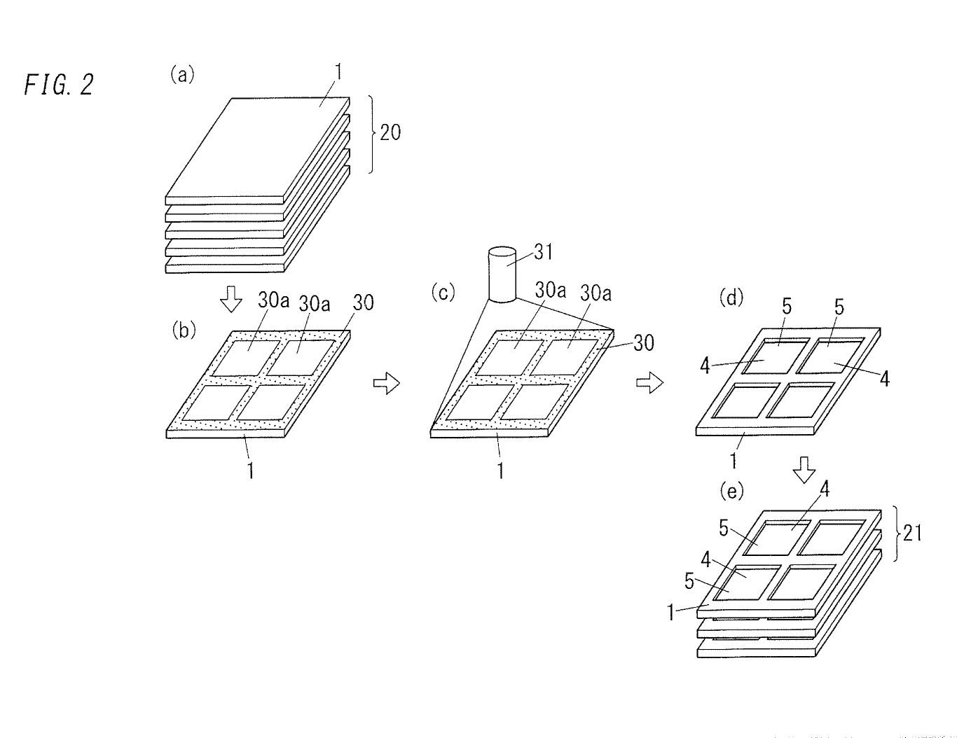

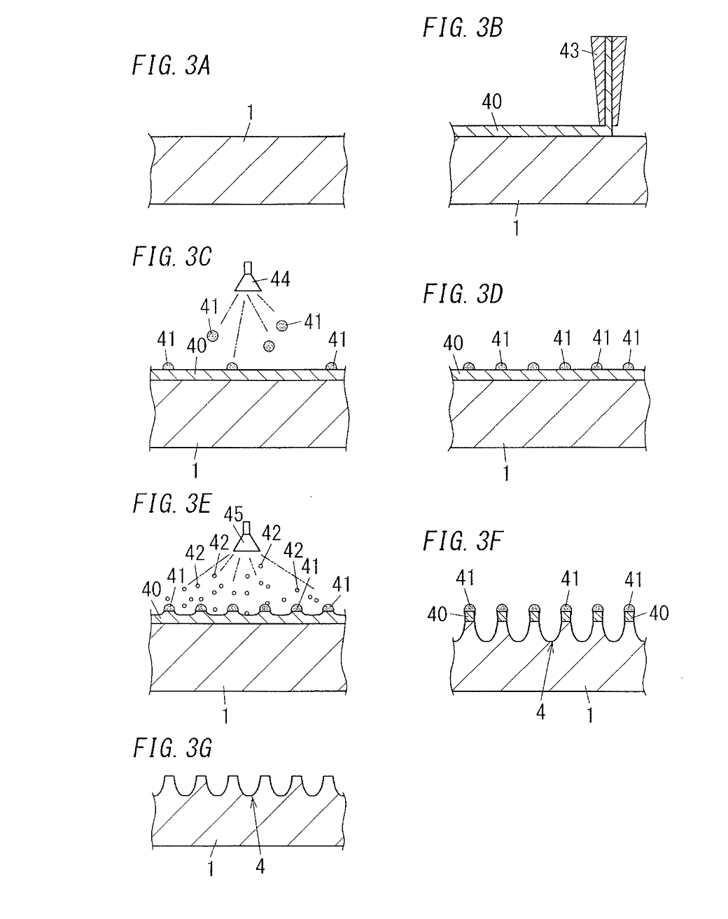

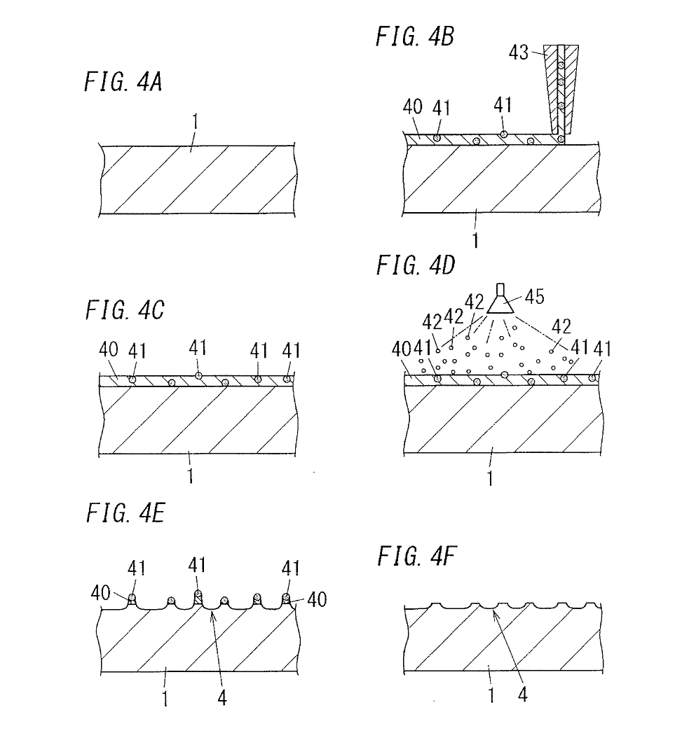

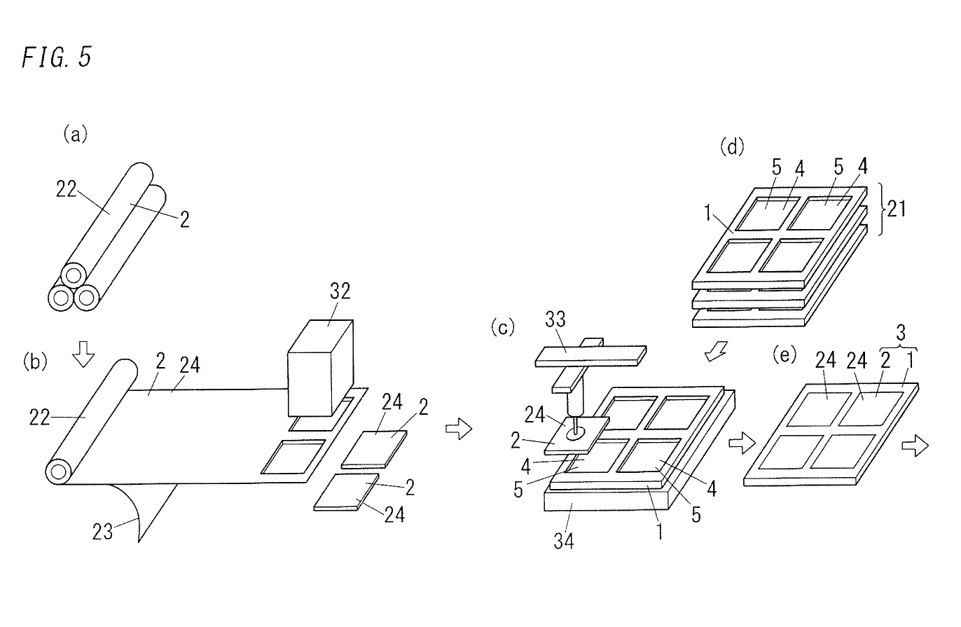

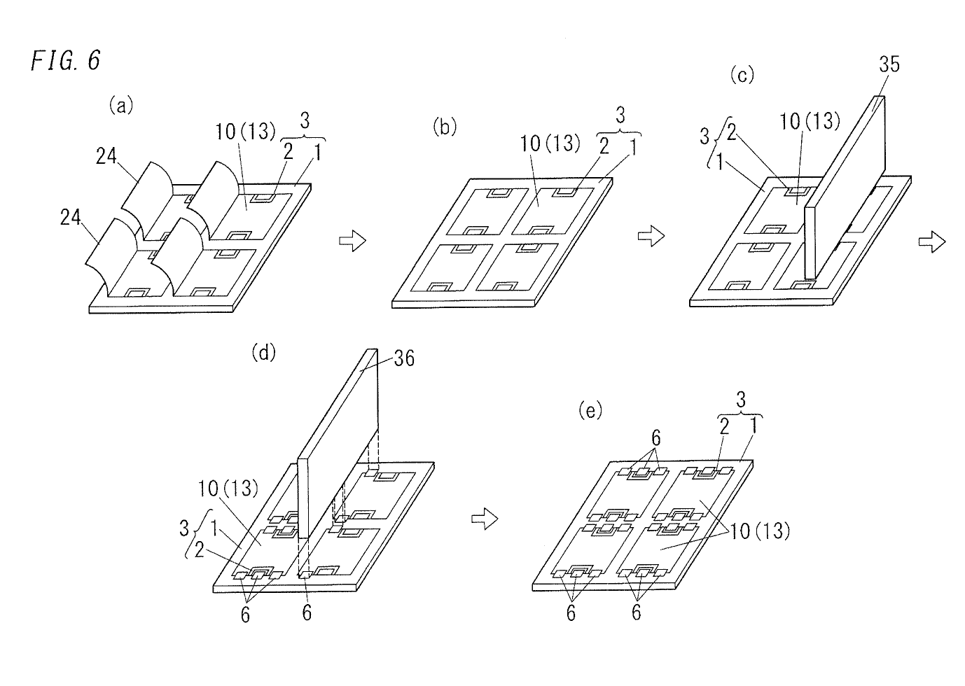

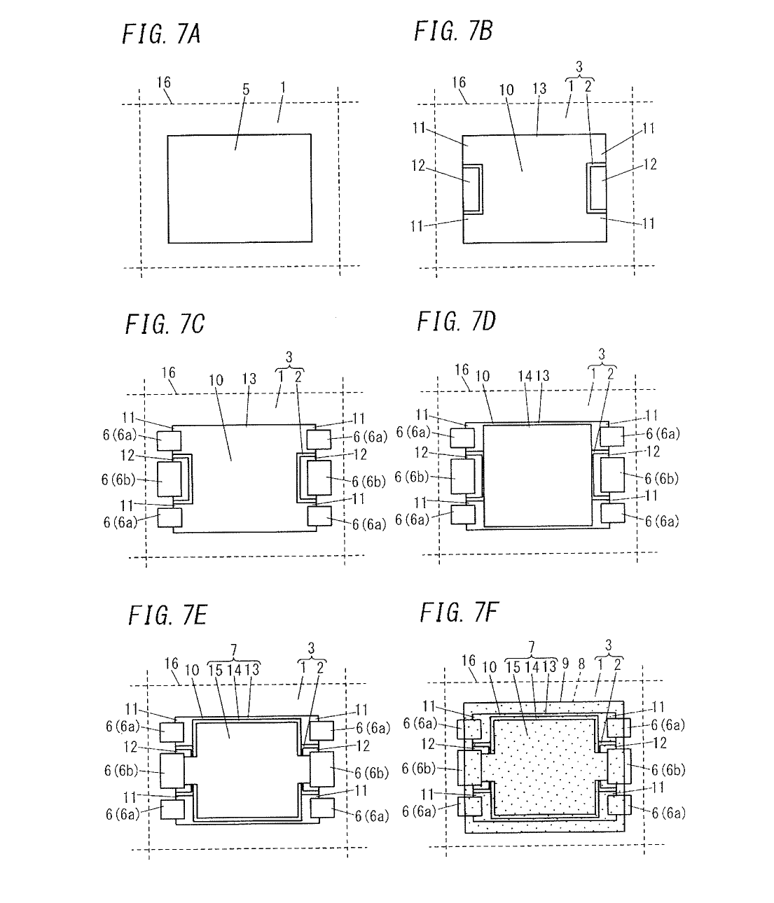

FIGS. 2 to 7 are views each illustrating an example of the production process for the organic EL element. FIG. 2 shows an example of the recess-forming step. FIG. 3A to 3G show an example of the roughening step. FIG. 4A to 4F show an example of the roughening step. FIG. 5 shows an example of the composite substrate-forming step. FIG. 6 shows an example of the electrode layer-forming step. FIG. 7A to 7F show an organic EL element in the intermediate state of manufacture. Described in the present embodiment is a method for preparing multiple organic EL elements by forming an integrated organic EL element composite in which multiple organic EL elements are connected to each other and cutting it into pieces. It is possible by the method of forming an integrated organic EL element composite to produce multiple organic EL elements simultaneously and thus to increase productivity. Hereinafter, each step will be described one by one.

### [Recess-Forming Step]

As shown in FIG. 2, a flat moisture-proof substrate 1 is first prepared in the recess-forming step. Then as shown in FIG. 2 (a), a moisture-proof substrate 1 can be withdrawn from a magazine 20 containing multiple moisture-proof substrates and sent to the digging step.

The moisture-proof substrate 1 for use may be a moisture-proof light-transmissive transparent substrate. The moisture-proof substrate 1 for use is preferably a glass substrate. If the moisture-proof substrate 1 is a glass substrate that has low water permeability, it is possible to suppress penetration of water into the covered region. The glass for use is, for example, a nonalkali glass, a soda-lime glass or the like. Since the organic electroluminescent laminate 7 is not formed directly on the glass substrate in the present embodiment, it is possible to use a cheaper soda-lime glass instead of expensive nonalkali glass. It is also possible to use a glass prepared by the common float process. If it is a glass prepared by the float process, the glass does not cause a problem of surface roughness, and therefore there is no need for polishing with an expensive abrasive. If a soda-lime glass is used, it is suitably an optical glass that is free from impurities, colorless and also free from air bubbles or deformation. An example of the optical glasses is white soda-lime glass. The white soda-lime glass for use may be, for example, a product from Matsunami Glass Ind., Ltd. The moisture-proof substrate 1 for use is, for example, a rectangular plate in the dimension of 730×920×0.7 mm (width×length×thickness), but it is not limited thereto.

The moisture-proof substrate 1 for use may be a flexible substrate. Examples of the flexible substrate include a flexible glass or a moisture-proof resin. When the moisture-proof substrate 1 is flexible, it is possible to obtain a flexible organic EL element.

Then as shown in FIG. 2 (b), the region of the surface of the moisture-proof substrate 1 other than a region where the recesses 5 are to be formed is covered with a mask 30. This is the masking step. The mask 30 for use may be, for example, a common mask material or pattern mask (shielding material). For example, a dry film mask may be used. Particularly when the recesses 5 are formed by sand blasting, a dry film mask for sand blasting may be used. The dry film mask for sand blasting for use may be a mask in the three-layer structure having a mask layer, a release film formed on one face of the mask layer and a carrier film formed on the other face. Such a dry film mask for sand blasting is commercially available, for example, from Mitsubishi Paper Mills Ltd. In FIGS. 2 (b) and (c), the area where the mask 30 is formed is indicated by dots.

The mask 30 has mask holes 30a in the regions corresponding to the recesses 5. In FIG. 2 (b), the mask 30 has multiple (four) identically shaped mask holes 30a formed in a pattern in which they are aligned lengthwise and crosswise. The mask pattern is not limited thereto and the mask holes 30a may be formed, for example, in a pattern of 3 (lengthwise)×3 (crosswise) (9) holes, 4 (lengthwise)×4 (crosswise) (16) holes or more. Alternatively, the mask holes 30a may be formed in a pattern in combination of different hole numbers, such as 2 (lengthwise)×3 (crosswise). Yet alternatively, only one mask hole 30a may be formed for production of an organic EL element.

Then as shown in FIG. 2 (c), recesses 5 are formed by digging the surface of the moisture-proof substrate 1 that is exposed through the mask holes 30a. The moisture-proof substrate 1 may be dug by any desired method suitable for forming the recesses 5. Examples of the method include sand blasting, etching and the like. In the recess-forming step, the recesses 5 are preferably formed on the surface of the moisture-proof substrate 1 by collision of particles. It is possible in this way to form the recesses 5 easily. It is also easy to form the recesses 5 and roughen the surface of the moisture-proof substrate 1 simultaneously. The mask 30 is removed after the recesses 5 are formed. As shown in FIG. 2 (d), the moisture-proof substrate 1 having multiple recesses 5 is obtained.

The (bottom) surface of the recesses 5 is preferably roughened in the recess-forming step. In such a case, the recess-forming step and roughening step are carried out simultaneously. It is possible in this way to form the recesses 5 and roughen the surface easily and efficiently. It is possible to form a light-outcoupling structure 4 easily by roughening the surface of the recess 5, which is the interface region between the moisture-proof substrate 1 and the resin film 2. Thus, the light-outcoupling structure 4 is defined by the roughened surface of the moisture-proof substrate 1. Specifically, the surface roughening gives fine surface unevenness, which causes light scattering and thus improves the viewing angle dependence of the element. As will be described below, the roughening step may of course be performed separately from the recess-forming step.

FIG. 2 (c) illustrates the sand blasting process of forming recesses 5 by digging the surface of the moisture-proof substrate 1. In the process, sand serves as the surface-roughening particles which are sprayed from nozzle 31. Compared to the common etching processes, the sand blasting process can be conducted at higher processing rate and at lower cost. Thus, a favorable example of the digging method is sand blasting process. The surface of the moisture-proof substrate 1 (glass surface) is roughened more easily by sand blasting. Surface roughening of the moisture-proof substrate 1 gives fine surface unevenness. It is thus possible to form the light-outcoupling structure 4 easily on the surface of the moisture-proof substrate 1 (bottom face of recess 5). The fine surface unevenness permits incorporation of gas as pores between the resin film 2 and the moisture-proof substrate 1 when the resin film 2 is adhered and gives a light-scattering structure due to the pores as light-outcoupling structure 4. Once the light-outcoupling structure 4 by the gas pores is formed, it is possible to reduce the refractive index in the region and increase the light-outcoupling efficiency. The gas incorporated is preferably an inactive gas such as nitrogen.

Alternatively, the recesses 5 may be formed by etching. The etching can be conducted, for example, using hydrofluoric acid. It is possible by etching to make the surface of the recess 5 smooth and flat.

The recesses 5 are more preferably prepared in a process in combination of the sand blasting process and the etching process. For example, it is possible to use a method of forming rough recesses by digging by means of sand blasting and etching the surface with an etchant such as hydrofluoric acid. The method permits increase of processing rate and also adjustment of surface roughness. Thus, it is possible to prepare the recesses 5 efficiently.

The depth of the recess 5 may be identical with or greater than the thickness of the resin film 2. Accordingly, the resin film 2 can be placed in the recess of the moisture-proof substrate 1 so that the surface of the resin film 2 is flush with the surface of the moisture-proof substrate 1 or the surface of the resin film 2 is recessed from the surface of the moisture-proof substrate 1. For example when a resin film 2 having a thickness of 0.05 mm is used, the depth of the recess 5 may be 0.05 mm or more.

The moisture-proof substrate 1 having recesses 5 can also be prepared by injecting a fluidal material for the moisture-proof substrate 1 into a mold and molding it under heat. The heat molding permits rapid production of the moisture-proof substrate 1 having recesses 5. However, generally, the method of forming recesses 5 by digging gives a smaller number of distorted products than the method of forming recesses 5 by heat molding and is thus preferable as the production method from the point of optical properties and dimensional accuracy. The method by digging is also advantageous in that the production cost is often lower, as no mold is needed in contrast to the heat molding method and in that the shape (dimension) of the recesses 5 can be modified easily. Thus, the method of forming recesses 5 by digging is employed in the present embodiment.

After the processing by digging, multiple pieces of the moisture-proof substrates 1 having recesses 5, as prepared in the steps above, are stacked and can be stored as a moisture-proof substrate magazine 21 before they are used in the following step.

### [Roughening Step]

The surface of the moisture-proof substrate 1 may be roughened, as described above, simultaneously with formation of the recesses 5. However, the roughening step may be carried out separately from the formation of recesses 5. It is possible in this way to roughen the surface at high accuracy. If a roughening step is additionally performed in the present embodiment, the (bottom) surface of the recess 5 after formation of recesses 5 can be roughened. If the surface is roughened simultaneously with formation of recesses 5, there is no need for carrying out the roughening step described below.

FIGS. 3A to 3G illustrate an example of the roughening step. FIGS. 3A to 3G show a method of applying an adhesive as a surface layer 40 on the surface of the moisture-proof substrate 1, adhering a protective member 41 on the surface layer 40 for protection of the moisture-proof substrate 1 from abrasion, and roughening the surface by spraying particles 42 on the protective member 41. Specifically in the roughening step, the surface of the moisture-proof substrate 1 is roughened after a protective member 41 is provided thereon. By providing the protective member 41, it is possible to form a roughened surface with random unevenness and thus to improve the light-outcoupling efficiency. In the case of the method shown in FIGS. 3A to 3G, the surface of the moisture-proof substrate 1 is roughened by collision of particles 42. When the surface is roughened by collision of particles 42, it is possible to form a roughened surface with high light-outcoupling efficiency easily. Although the surface may be roughened by etching with hydrofluoric acid through a photomask, it is possible by the method shown in FIGS. 3A to 3G to roughen the surface easily at low cost because the masking with the surface layer 40 is simpler and the processing rate is higher. In contrast to etching with hydrofluoric acid, which is an isotropic process, the method often gives an anisotropic processed surface and thus a structure having a higher aspect ratio. When a protective member 41 is sprayed as seeds, it often gives a random structure due to the seed spraying. It is thus possible to easily obtain a structure higher in light-outcoupling efficiency.

First in the surface roughening, an adhesive shown in FIG. 3B is applied onto the surface of the moisture-proof substrate 1 (bottom face of the recess 5) shown in FIG. 3A, forming an adhesive surface layer 40. The adhesive for use is an adhesive that is higher in adhesive force, permits uniform application and gives a coated film highly adhesive to the protective member 41. It is possible, for example, to use an ultraviolet-hardening resin or a heat-hardening resin and typical examples thereof include, but are not limited to, epoxy resins, silicone resins and the like. After application of the adhesive, the resin constituting the coated film is preferably converted into the semi-hardened state (so-called B stage) by ultraviolet irradiation when an ultraviolet-hardening resin is used or by heating when a heat-hardening resin is used. The resin in the semi-hardened state give a film with adhesive power and integrity. The adhesive can be applied using a common coating device 43. Examples thereof include slit coaters, spin coaters, spray coaters and the like. FIG. 3B shows an example using a slit coater. Alternatively, a sheet-shaped adhesive may be adhered to the surface of the moisture-proof substrate 1, forming a surface layer 40. The surface layer 40 is a layer to be scraped by collision of particles 42 in the following step.

Then as shown in FIG. 3C, a protective member 41 is sprayed with a spraying device 44 and adhered to the adhesive surface layer 40. The protective member 41 for use is preferably a material resistant to scraping by collision of particles 42. Accordingly, the surface of the moisture-proof substrate 1 is protected during collision of particles 42 in such a manner that parts of the moisture-proof substrate 1 are not scraped. It is possible in this way to form a roughened surface. The protective member 41 may be a particulate substance. It is thus possible to form a roughened surface with fine surface unevenness. When a particulate protective member 41 is used, it is possible to form dot-like protrusions distributed on the roughened face.

The protective member 41 is preferably a material harder than the particles 42 used for blasting. For example, when the particle 42 is alumina (Al₂O₃, hardness: 12), the protective member 41 for use may be SiC or diamond (hardness: 13). Alternatively when the particle 42 is zirconia (hardness: 11), the protective member 41 for use may be alumina (Al₂O₃, hardness: 12). When the protective member 41 used is alumina, the protective member 41 may not be removed and may be retained after surface-roughening of the moisture-proof substrate 1, to make the protective member 41 serve as a light-scattering material. The particle diameter of the protective member 41 is not particularly limited, but preferably in the range of 1 to 50 μm, more preferably in the range of 5 to 30 μm. The spraying device 44 favorable for use may be a spray coater. When a spray coater is used, it is possible to set the spraying condition easily. It is possible to regulate the aspect ratio and the scattering frequency of the light scattering structure formed by the roughened surface, by controlling the density of the protective member 41 during spraying.

Then as shown in FIG. 3D, the surface layer 40 which is semi hardened can be hardened completely, for example, under a hardening condition of ultraviolet ray or heat. If it is hardened by ultraviolet ray irradiation, it is preferable to irradiate the ultraviolet ray from the side of the moisture-proof substrate 1 opposite to the surface layer 40, because the region hidden behind the protective member 41 may not be hardened if the ultraviolet ray is irradiated from the side of the surface layer 40. As the adhesive constituting the surface layer 40 is hardened completely, the protective member 41 binds to the surface layer 40 tightly. It is thus possible to reduce scattering and removal of the protective member 41 by spraying particles 42. The protective member 41 is preferably embedded partially in the surface layer 40. It makes the protective member 41 retained in the surface layer 40 without separation from the surface layer 40. It is possible to embed part of the protective member 41 in the surface layer 40, by properly adjusting the spraying force of the spraying device 44.

As shown in FIG. 3E, the particles 42 are blasted to the surface of the surface layer 40 by a blasting device 45. The particles 42 can be blasted by the so-called sand blasting process. It is thus possible to conduct blasting by ejecting the particles 42 continuously through a blast nozzle. It is also possible to eject particles 42 at high pressure and improve the scraping efficiency of the moisture-proof substrate 1. The particle 42 favorable for use is a particle lower in hardness than the protective member 41 and higher in hardness than the moisture-proof substrate 1. It is thus possible to scrape the moisture-proof substrate 1 efficiently. When the moisture-proof substrate 1 is made of glass, the particle 42 preferably has hardness higher than that of glass. The particle 42 for use may be, as described above, alumina, zirconia or the like. The diameter of the particles 42 is not particularly limited, but preferably in the range of 1 to 30 μm, more preferably in the range of 1 to 20 μm. The diameter of the particles 42 is preferably smaller than that, of the protective member 41. It is thus possible to scrape the moisture-proof substrate 1 more easily. For example, the particle diameter of the particles 42 may be half of that of the protective member 41 or less.

By blasting with particles 42, the particles 42 collide the surface layer 40, scraping the part of the surface layer 40 where no protective member 41 is adhered. If the particles 42 continue colliding further, the part of surface layer 40 is removed, as scraped, and the depth of the scraped region reaches the surface of the moisture-proof substrate 1, and furthermore the moisture-proof substrate 1 is then scraped. It is possible in this way to scrape the moisture-proof substrate 1 partially in the region where there is formed no protective member 41 by collision of particles 42.

FIG. 3F shows the moisture-proof substrate 1 scraped by collision of particles 42. If the protective member 41 has a light-scattering property, the moisture-proof substrate 1 carrying the adhered protective member 41 shown in FIG. 3F may be used as it is without removal of the protective member 41 in the following step. In such a case, the light-outcoupling structure 4 may be defined by the unevenness on the surface of the moisture-proof substrate 1 and the protective member 41. For example when the protective member 41 is alumina, the protective member 41 may be left unremoved. It is possible when the protective member 41 is not removed to simplify the production process and facilitate the production.

FIG. 3G shows the moisture-proof substrate 1 after removal of the protective member 41 and the surface layer 40. If the protective member 41 and the surface layer 40 do not serve for offering optical advantages, it is preferable to remove the protective member 41 and the surface layer 40. For example, the protective member 41 and the surface layer 40 can be removed by dissolving with solvent and washing off the surface layer 40. In the moisture-proof substrate 1, the light-outcoupling structure 4 is defined by the surface unevenness.

When the moisture-proof substrate 1 is scraped by collision of particles 42, as in the method shown in FIGS. 3A to 3G, it is possible to form a light-scattering structure having high-aspect ratio and to improve the light-outcoupling efficiency.

FIGS. 4A to 4F show another embodiment of the roughening step. FIGS. 4A to 4F show a method of forming a surface layer 40 containing a protective member 41 on the surface of the moisture-proof substrate 1 and roughening the surface by blasting with particles 42. Thus in the roughening step, the protective member 41 is provided and then the surface of the moisture-proof substrate 1 is roughened. It is possible in the presence of the protective member 41 to form a roughened surface with random surface unevenness and thus to improve the light-outcoupling efficiency. Also in the method shown in FIGS. 4A to 4F, the surface of the moisture-proof substrate 1 is roughened by collision of particles 42. Surface roughening by collision of particles 42 gives a roughened surface with high light-outcoupling efficiency easily. The protective member 41 may be a particulate substance. The protective member 41 is formed on the surface of the moisture-proof substrate 1 more easily by the method shown in FIGS. 4A to 4F than by the method shown in FIGS. 3A to 3G, as the particles 42 are contained previously in the material for the surface layer 40. However, the method shown in FIGS. 3A to 3G may be advantageous for adjustment for example of the density of the protective member 41. It is because it is possible to adjust the density of the protective member 41 easily by modification of the spraying condition of the spraying device 44.

It is also possible to conduct surface roughening easily at low cost by the method shown in FIGS. 4A to 4F, as the mask processing by the surface layer 40 is simple and rapid. In addition, the method often gives an anisotropically processed surface, in contrast to hydrofluoric acid etching, which gives an isotropic surface, and thus, makes it easier to give a structure with higher aspect ratio. It is thus possible to obtain a structure with high light-outcoupling efficiency easily.

First in the surface roughening, a surface layer 40 is formed on the surface (bottom face of a recess 5) of the moisture-proof substrate 1 shown in FIG. 4A by coating with a coating agent, as shown in FIG. 4B. A particulate protective member 41 is dispersed in the coating agent. The coating agent for use may be an agent that is higher in adhesive force and can be applied uniformly into the form of film. For example, an ultraviolet- or heat-hardening resin is used favorably, and typical examples thereof include, but are not limited to, epoxy resins, silicone resins and the like. After application of the coating agent, the resin in the coated film is hardened by ultraviolet irradiation when an ultraviolet-hardening resin is used or by heating when a heat-hardening resin is used. The hardening then may be complete hardening. The coating agent can be applied using an appropriate coating device 43. For example, a slit coater, a spin coater or a spray coater may be used. FIG. 4B shows an example wherein a slit coater is used. Alternatively, the surface layer 40 may be formed by adhering a sheet-shaped adhesive containing a protective member 41 to the surface of the moisture-proof substrate 1. The protective member 41 is bonded to the surface layer 40 tightly, as the adhesive for the surface layer 40 is hardened completely. It is thus possible to suppress scattering of the protective member 41 by blasting with particles 42. As shown in FIG. 4C, hardening of the surface layer 40 gives a surface layer 40 containing the protective member 41, the protective member 41 being dispersed in the surface layer 40.

As shown in FIG. 4D, the particles 42 are blasted to the surface of the surface layer 40 by a blasting device 45. The particles 42 can be ejected by the so-called sand blasting process. The materials for the protective member 41 and the particles 42 for use are similar to those described in FIGS. 3A to 3G. Specifically, the particle 42 for use is a particle lower in hardness than the protective member 41. The diameter of the particles 42 is preferably smaller than that of the protective member 41.

By blasting with particles 42, the particles 42 collide with the surface layer 40, scraping the part of the surface layer 40 where the protective member 41 is not provided thereon. If the particles 42 continue colliding further, the part of the surface layer 40 is scraped and then is removed, and the scraped region reaches the surface of the moisture-proof substrate 1, and the moisture-proof substrate 1 is then scraped further. It is possible in this way to scrape the moisture-proof substrate 1 by collision of particles 42 partially in the region where the protective member 41 is not provided.

FIG. 4E shows the moisture-proof substrate 1 scraped by collision of particles 42. If the protective member 41 has a light-scattering property, the moisture-proof substrate 1 carrying the adhered protective member 41 shown in FIG. 4E may be used as it is without removal of the protective member 41 in the following step. In such a case, the light-outcoupling structure 4 may be defined by the unevenness on the surface of the moisture-proof substrate 1 and the protective member 41. For example when the protective member 41 is alumina, the protective member 41 may be left unremoved. It is possible when the protective member 41 is not removed to simplify the production process and make the production easier.

FIG. 4F shows the moisture-proof substrate 1 after removal of the protective member 41 and the surface layer 40. If the protective member 41 and the surface layer 40 do not serve for offering optical advantages, it is preferable to remove the protective member 41 and the surface layer 40. The protective member 41 and the surface layer 40 can be removed, for example, by dissolving and washing off the surface layer 40 with solvent. In this moisture-proof substrate 1, the light-outcoupling structure 4 is defined by the surface unevenness.

The moisture-proof substrate 1 of which surface is roughened by the method shown in FIGS. 3A to 3G or FIGS. 4A to 4F can be used as a member of a composite substrate 3.

If the recess-forming step is conducted by the sand blasting process and the roughening step also by the sand blasting process as shown in FIGS. 3A to 3G or FIGS. 4A to 4F, the sand blasting processes in the recess-forming step and in the roughening step are preferably conducted under a similar condition (material, apparatus). In this case, for example, the protective member 41 and the surface layer 40 may be provided during the sand blasting process. In such a case, the recess-forming step and the roughening step can be carried out continuously, which makes production easier.

### [Composite Substrate-Forming Step]

First in the composite substrate-forming step, a roll 22 is prepared by rolling a long resin film 2 made available, as shown in FIG. 5 (a). The roll 22 is normally assured to be free from stains or damages by product inspection. The roll 22 for use may be a product prepared by stretching a resin under pressure by rolling.

The resin film 2 for use is preferably a flexible material. When it is flexible, it is possible to insert a resin film 2 into the recess 5 of the composite substrate 3, while supplying the long resin film 2 from the roll 22, and produce the composite substrate 3 sequentially. Thus the composite substrate 3 is produced efficiently and easily. If a flexible composite substrate 3 can be obtained from a flexible moisture-proof substrate 1 and a flexible resin film 2, a flexible organic EL element can be obtained.

The resin film 2 may be, for example, made of a plastic material. The plastic material for use may be a molded article (such as sheet or film) obtained by molding and hardening a synthetic resin for plastic materials. The plastic substrate for use is, for example, made of a plastic material such as PET (polyethylene terephthalate) or PEN (polyethylene naphthalate). The molding may be roll molding. When the roll molding is used, a resin film 2 higher in light-outcoupling efficiency can be obtained more easily.

The refractive index of the resin film 2 is preferably equivalent to that of the first electrode 13. It is possible to suppress total reflection due to difference in refractive index, when the refractive index of the resin film 2 is closer to that of the first electrode 13. For example, it is possible to make the difference in refractive index between the resin film 2 and the first electrode 13 not larger than 1. A high-refractive index plastic material may be used for the resin film 2 to reduce the difference in refractive index.

The resin film 2 in the roll 22 for use preferably has protective films 23 and 24 adhered to both faces thereof. The protective films 23 and 24 formed on the surfaces can reduce staining and damaging of the resin film.

A resin film 2 in the roll 22 may carry an electroconductive layer 10 on the surface. The electroconductive layer 10 is an optically transparent electroconductive layer to serve as the first electrode 13, a first electrode extension 11 and a second electrode extension 12 (see FIG. 6). The electroconductive layer 10 is, for example, a thin film metal or a layer of an optically transparent metal oxide (such as ITO). It is possible to improve productivity by using a resin film 2 carrying an electroconductive layer 10 previously formed. Then, the electroconductive layer 10 is preferably formed in a pattern including the part for the first electrode 13 and the first electrode extension 11 and the part for the second electrode extension 12 which are separated from each other. Such an electroconductive layer eliminates the need for patterning for example by removal of the electroconductive layer 10 in the later step, making it possible to increase the productivity. The electroconductive layer 10 may be formed by sputtering. If the resin film 2 in the roll carries an electroconductive layer 10 previously formed, the protective film 24 is preferably adhered to the external surface of the electroconductive layer 10.

In the present embodiment, the resin film 2 for use may be a resin film 2 carrying a patterned electroconductive layer 10 on one face and having protective films 23 and 24 on both faces. When the electroconductive layer 10 is previously formed, the protective film 24 may be adhered to the face of the electroconductive layer 10, while the protective film 23 is adhered to the face opposite to the electroconductive layer 10. The resin film 2 for use may be a PEN film carrying an electroconductive film that is protected on both faces with protective films 23 and 24. The roll 22 of PEN film is, for example, a roll of a PEN film of 0.05 mm in thickness, 730 mm in width and 50 in in length, but it is not limited to thereto.

As shown in FIG. 5 (b), an integrated long resin film 2 is supplied from the roll 22, the protective film 23 on the bottom face (the face not carrying the electroconductive layer 10) is removed by peeling, and the individual resin films 2 are prepared by punching. The punching is carried out using a sheet puncher 32 in FIG. 5 (b). When the resin film carries the electroconductive layer 10 on the surface, it is punched out according to the pattern pitch of the electroconductive layer 10, so that the electroconductive layer 10 on the resin film obtained after punching has a pattern shape desired for an element. The resin film 2 punched out has a dimension similar to that of the recess 5 formed in the moisture-proof substrate 1. The surface of the resin film 2 after removal of the protective film 23 may be cleaned, but may not be cleaned if there is no optical problem. The protective film 23 may be peeled off after punching. If it is removed after punching, a peeling step of peeling off the film one by one may be provided.

Then as shown in FIG. 5 (c), a moisture-proof substrate 1 having recesses 5 is withdrawn from the magazine 21 shown in FIG. 5 (d) containing the moisture-proof substrates having recesses formed thereon, and a resin film 2 is inserted into and adhered to the recess 5. The resin film 2 can be adhered using an adhering device 33. The adhering device 33 places and fixes the moisture-proof substrate 1 on a mounting table 34 and transfers the resin film 2 into the recess 5 of the moisture-proof substrate 1 in the floated state, for example by holding the resin film 2 by suction on the surface (top face) and releasing it by termination of suction. An example of the adhering device 33 that may be used is a device manufactured by Climb Products Co., Ltd. For prevention of incorporation of air bubbles, the resin film 2 may be adhered under reduced-pressure atmosphere. In addition, the resin film 2 may be adhered by a roll-shaped tool. An adhesive may be used for adhesion. Alternatively, the resin film 2 may be adhered by thermal compression. The adhesion is preferably conducted as the protective film 24 is still present on the surface of the resin film 2. It is possible accordingly to suppress deposition of foreign matter and damaging on the surfaces of the electroconductive layer 10 and the resin film 2.

The film in the roll 22 for use may be a laminate film (precut film) of a continuous protective film 23, and a protective film 24 and a resin film 2 that are previously cut into pieces (namely, precut products). It is a tack seal-type resin film 2. In such a case, the resin film 2 protected with protective film 24 can be peeled off from the continuous protective film 23 and inserted into the recess 5, as it is, and adhered to the moisture-proof substrate 1. Also in this case, the electroconductive layer 10 may be formed in advance. The precutting is preferably made according to the pattern pitch of the electroconductive layer 10.

The resin film 2 may be cut by laser irradiation. It is possible to process the end face of the cut product accurately by laser cutting. In the case of laser cutting, it is possible by adjustment of laser output to cut only the top-sided protective film 24 and the resin film 2 and leave the bottom-sided protective film 23 uncut. It then gives a tack seal-type resin film 2. Then, the resin film 2 protected by the protective film 24 can be peeled off from the continuous protective film 23, inserted into the recess 5, as it is, and adhered to the moisture-proof substrate 1. Also in this case, the electroconductive layer 10 may be formed in advance. The laser cutting is preferably conducted according to the pattern pitch of the electroconductive layer 10. Although the entire film may be disintegrated by laser irradiation after removal of the bottom-sided protective film 23 in the laser processing, similarly to punching, it is preferable to leave the bottom-sided protective film 23 continuous, as it is not disintegrated, for reduction of the possibility of contamination by foreign matter.

In the step above, a resin film 2 is fitted into the recess 5 of the moisture-proof substrate 1, giving a composite substrate 3 of the moisture-proof substrate 1 and the resin film 2, as shown in FIG. 5 (e). However, the resin film 2 still carries the protective film 24 adhered on the surface. The composite substrate 3 can be stored in that state. The protective film 24 adhered prevents damaging and contamination by foreign matter on the surface.

### [Preparation for Electrode Layer-Forming Step]

After the processing shown in FIG. 5 (e), the protective film 24 is peeled off from the resin film 2, as shown in FIG. 6 (a). When a roll 22 of a resin film 2 carrying an electroconductive layer 10 is used, the electroconductive layer 10 for the first electrode 13 becomes exposed, as shown in FIG. 6 (b). If the adhesive for adhesion of the protective film 24 gives adverse effects as it remains there, the surface may be cleaned for removal of the adhesive. The cleaning may be conducted only on the side of the surface where the protective film 24 is peeled off. In the embodiment shown in FIG. 6 (b), the electroconductive layer 10 has a pattern shape including a H-shaped part containing a first electrode 13 and two I-shaped parts in the openings outside the H-type region.

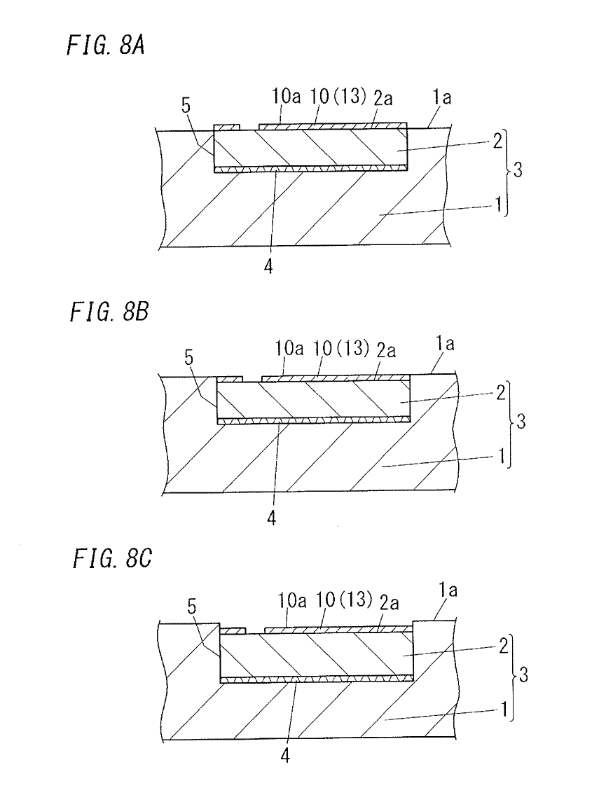

Examples of the composite substrates 3 in which resin films 2 are embedded in the moisture-proof substrate 1 are shown in FIGS. 8A to 8C.

FIG. 8A shows an example of the composite substrate 3 wherein the surface 2a of the resin film 2 is substantially flush with the surface 1a of the moisture-proof substrate 1 in the thickness direction. Thus, the surface of the composite substrate 3 is nearly flat and the electroconductive layer 10 is formed on this surface. FIG. 8B and FIG. 8C show examples of the composite substrate 3 wherein the surface 2a of the resin film 2 is lower than the surface 1a of the moisture-proof substrate 1 in the thickness direction. In FIG. 8B, the resin film 2 is embedded entirely in the moisture-proof substrate 1 and the surface 10a of the electroconductive layer 10 is in almost the same position in the thickness direction as the surface 1a of the moisture-proof substrate 1. The surface 10a of the electroconductive layer 10 may be higher than the surface 1a of the moisture-proof substrate 1 in the thickness direction. In FIG. 8C, the entire resin film 2 is embedded further in the moisture-proof substrate 1 and the surface 10a of the electroconductive layer 10 is lower than the surface 1a of the moisture-proof substrate 1 in the thickness direction. For favorable preparation of the electrode layer 6 and the organic electroluminescent laminate 7, the surface 10a of the electroconductive layer 10 is preferably formed so as to be flush with or higher than the surface 1a of the moisture-proof substrate 1, so that the electroconductive layer 10 is not embedded in the composite substrate 3, as shown in FIGS. 8A and 8B. However, for reduction of thickness, it is also possible to employ the configuration in which the resin film 2 carrying the electroconductive layer 10 is fitted into the recess 5 to such a degree that the side wall of recess 5 is exposed, as shown in FIG. 8C.

The organic EL element shown in FIGS. 1A and 1B is an example of the element that is prepared using a composite substrate 3 in which the surface of the resin film 2 is at the same level as the level of surface of the moisture-proof substrate 1 in the thickness direction, as shown in FIG. 8A. Of course, the organic EL element may be prepared using a composite substrate similar to the composite substrate 3 shown in FIG. 8B or 8C.

As shown in FIG. 6 (c), the composite substrate 3 formed after the protective film 24 is peeled off is inspected. The inspection can be performed by an appearance-inspecting machine 35. The inspection may include inspection of the surface of the resin film 2 and inspection of the interface between the resin film 2 and the moisture-proof substrate 1. It is possible in this case to perform the inspection efficiently by observation under two cameras different in focal length setting.

Contamination by foreign matter and incorporation of air bubbles are examined in the inspection. The air bubbles may cause a problem in appearance, but may be ignored if they do not have a size discernible with naked eyes. For example if air bubbles having a diameter (as approximate sphere) of 0.2 mm or more are contained when seen from the angle perpendicular to the surface of the composite substrate 3, the composite substrate is considered unfavorable. When air bubbles in the size unrecognizable by naked eyes are contained, the light-outcoupling efficiency sometimes may improve, as described above.

As the presence of foreign matter affects the light-outcoupling efficiency, the presence of foreign matter is examined. In particular, foreign matter on the surface of the resin film 2 is extremely disadvantageous to the organic electroluminescent laminate 7 and the presence of foreign matter should be examined strictly. For example when foreign matters having a diameter of several μm or more (e.g., 3 μm) are contained, the composite substrate may be considered to be unfavorable.

The composite substrate 3 that satisfies the visual inspection is sent to the next electrode layer-forming step.

### [Electrode Layer-Forming Step]

First in the electrode layer-forming step, the surface on which the electrode layer 6 is to be formed is preferably modified in advance. The surface modification is a process to improve the wettability thereof to ink. The surface modification can be conducted by irradiation of VUV or plasma. Then, electrode layers 6 are formed on the modified surface. As shown in FIG. 6 (d), the electrode layers 6 are formed across the boundary regions between the resin film 2 and the moisture-proof substrate 1.

The electrode layer 6 can be formed, for example, by printing, plating, sputtering or ion plating. Among the methods above, the electrode layer 6 is preferably formed by printing. Printing permits easy and efficient preparation of the electrode layer 6. The printing is preferably inkjet printing. Inkjet printing permits easy and accurate preparation of a patterned electrode layer 6. Of course, a printing method other than inkjet printing may be used. Sputtering, which is lower in film-forming velocity, often demands an extended period of time. Although ion plating is higher in film-forming velocity, it often causes pattern blurring on the resin film 2 due to gas release when the electrode layer 6 is formed on the surface. Although plating is higher in film-forming velocity, it is slower when compared with printing, and it makes the plating step complicated, possibly making it harder to prepare the film. In contrast, it is possible by printing to form a thick electrode layer 6 easily. In addition, since printing can form a thick layer easily, it can prevent cleavage of the electrode layer 6 at the boundary region between the resin film 2 and the moisture-proof substrate 1. That is, when the electrode layer 6 is thin, the electrode layer 6 may be broken for example by later heat treatment because of the difference in thermal expansion coefficient between the resin film 2 and the moisture-proof substrate 1, but it is possible by printing to prevent such breakage of the electrode layer 6, because it can increase the thickness of the electrode layer 6 easily. For prevention of the cleavage of the electrode layer 6, the thickness of the electrode layer 6 is preferably, for example, 1 μm or more. Alternatively for reduction of thickness, the thickness of the electrode layer 6 is preferably 100 μm or less, but is not limited thereto.

The material used for preparing the electrode layer 6 may be any conductive material. The electrode layer 6, which is formed across the boundary region between the moisture-proof substrate 1 and the resin film 2 and thus vulnerable to breaking force, as described above, is preferably made of a hard material. In the case of printing, silver nanopaste (nanometer-sized silver particles in the paste form) may be used, but the material is not limited thereto.

FIG. 6 (d) shows an electrode layer 6 being formed by an inkjet printer 36. The electrode layer 6 is formed then across the boundary region between the resin film 2 and the moisture-proof substrate 1. Multiple (at least two) electrode layers 6 are preferably formed for preparation of layers serving as the electrode terminals for the first electrode 13 and the second electrode 15.

When an electroconductive layer 10 is formed on the surface of the resin film 2, the electrode layers 6 are formed in contact with the electroconductive layer 10. A first electrode layer 6a in contact with the electroconductive layer 10 constituting the first electrode 13 and the first electrode extension 11 and a second electrode layer 6b in contact with the electroconductive layer 10 constituting the second electrode extension 12 are formed then. The thickness of the electrode layer 6 may be larger than that of the electroconductive layer 10. It is thus possible to improve the electrical conductivity and to form a structure more resistant to water penetration by surrounding the side area of the organic electroluminescent laminate 7 with the electrode layer 6 or by surrounding the external surface of the organic electroluminescent laminate 7 with the electrode layer 6 when the organic electroluminescent laminate 7 is covered (see FIGS. 1A and 1B).

The electrode layer 6 is preferably made of a conductive material with lower water permeability. For example, the electrode layer 6 is preferably a metal material. The electrode layer 6 preferably has an electric resistance lower than that of the electroconductive layer 10. In such a case, the electrode layer 6 can serve as a supporting electrode assisting current flow and improve electrical conductivity to the electrode. In particular when planar emission is desirably obtained, unfavorable current flow may cause emission irregularity in the plane. However, it is possible to make the planer light emission more uniform by forming a more electrically conductive electrode layer 6.

When the electroconductive layer 10 is not formed previously on the surface of the resin film 2, it is possible to form the first electrode 13, the first electrode extension 11 and the second electrode extension 12 in the electrode layer-forming step. For example, an optically transparent electroconductive layer 10 may be formed on the surface of the resin film 2 entirely or in a patterned state and then, electrode layers 6 formed at proper positions at the periphery.

When the electroconductive layer 10 is not formed previously on the surface of the resin film 2, the electroconductive layer 10 may also serve as the electrode layer 6. Specifically, the electroconductive layer 10 extends across the boundary region between the resin film 2 and the moisture-proof substrate 1 to the end region of the moisture-proof substrate 1 and serves as the electrode terminal. In this case, the electrode layer 6 formed by part of the electroconductive layer 10 is an optically transparent layer. In this case, the electroconductive layer 10 may be formed so as to cover the entire exposed surface of the resin film 2, and the isolated region of the electroconductive layer 10 for the second electrode extension 12 may be formed on the surface of the moisture-proof substrate 1.

After preparation of the electrode layer 6, the resultant substrate is preferably heated. The heating raises the hardness of the electrode layer 6. The heating is conducted, for example, in an oven or on a hot plate. The heating temperature is preferably lower than the heat-resistance temperature of the resin film 2. For example in the case of PEN, the heating temperature may be 200° C. or lower. A material that can be heated at low temperature is, for example, silver nanoparticle ink. When the electrode layer 6 is formed by plating or sputtering, the resulting substrate is preferably annealed. The annealing temperature is preferably lower than the heat-resistance temperature of the resin film 2. The favorable plating material is, for example, nickel because nickel deposits tightly both on glass and plastics. The electrode layer 6 may be formed by multiple film-forming methods, for example by forming a seed layer by sputtering or printing and plating the surface thereon. Also in that case, a printing process, if included, makes it easier to form a thick electrode layer 6.

In this way, the electrode layers 6 are stacked and a composite substrate 3 carrying the electrode layers 6 on the surface, as shown in FIG. 6 (e), is obtained. The composite substrate 3 is then sent to the following step.

### [Electroluminescent Laminate-Forming Step and Covering Step]

FIGS. 7A to 7F show the moisture-proof substrate 1 in the intermediate state for preparation of the organic EL element, as seen from the direction perpendicular to the surface thereof. FIGS. 7A to 7F show the region divided by division lines 16 along which the organic EL element is cut into pieces. FIGS. 7A to 7C, among them, show the states after the respective steps described above. Specifically, FIG. 7A shows the moisture-proof substrate 1 carrying a recess 5 formed in the recess-forming step with the bottom face roughened in the roughening step. FIG. 7B shows the composite substrate 3 in which a resin film 2 carrying an electroconductive layer 10 is inserted into the recess 5 of a moisture-proof substrate 1 in the composite substrate-forming step. FIG. 7C shows a composite substrate 3 having electrode layers 6 formed on the end regions of the electroconductive layer 10 in the electrode layer-forming step. An organic electroluminescent laminate 7 is formed by lamination after the state shown in FIG. 7C.

The organic electroluminescent laminate 7 is formed, using a common lamination process. First as shown in FIG. 7D, an organic layer 14 is formed by lamination on the surface of the first electrode 13 in the central region of the electroconductive layer 10. The organic layer 14 can be formed by sequentially stacking the layers constituting the organic layer 14 through vapor deposition or coating. The organic layer 14, which is a layer having a function to emit light, has multiple layers properly selected from hole-injecting layer, hole-transporting layer, light-emitting layer, electron-transporting layer, electron-injecting layer, intermediate layer and the like. The organic layer 14 is formed in such a pattern that the second electrode 15 does not brought into contact with the first electrode 13 when the second electrode 15 is laminated.

Then as shown in FIG. 7E, a second electrode 15 is formed on the surface of the organic layer 14. Then, the second electrode 15 is laminated also on the surface of the second electrode extension 12 so as not to be in contact with the first electrode 13, the first electrode extension 11 and the first electrode layer 6a. The second electrode 15 may be formed so as to be in contact with the second electrode layer 6b. It is thus possible to assure current flow between the second electrode 15 and the second electrode layer 6b and thus to increase the function to assist current flow to the electrode. In this way, the organic electroluminescent laminate 7 is formed on the surface of the composite substrate 3.

As shown in FIG. 7F, a sealant adhesive is applied to a region larger than the resin film 2 in a plan view and a covering substrate 8 is adhered with an adhesive sealing layer 9. The region where the adhesive sealing layer 9 is formed is indicated by dots in FIG. 7F. Then, the adhesive sealing layer 9 is formed in such a position that the end region of the electrode layer 6 extends out of the region covered with the covering substrate 8 (covered region) and is exposed outward. In this way, the electrode layer 6 can serve as an electrode terminal. The sealant adhesive for use is an adhesive having both moisture-proof and insulating properties.

The covering substrate 8 for use may be a low-water permeable material. It is, for example, a glass film or a metal film. The covering substrate 8 may or may not have a recess for housing the organic electroluminescent laminate 7. If the covering substrate 8 has no recess, covering can be conducted by situating the covering substrate 8 in such a manner that a flat face of the covering substrate 8 faces the composite substrate 3. Thus, it is possible to use the flat substrate as it is, making it easier to produce the element.

An integrated continuous substrate may be used as the covering substrate 8 similarly to the moisture-proof substrate 1. Use of such an integrated covering substrates 8 permits simultaneous covering of multiple elements and thus improvement of productivity.

In this way, the individual organic electroluminescent laminate 7 is covered by bonding the composite substrate 3 to the covering substrate 8 with the adhesive sealing layer 9, giving an integrated organic EL element composite. Finally, it is possible to obtain organic EL elements by cutting the moisture-proof substrate 1 along the division lines 16 in the boundary regions of respective organic EL elements. When an integrated covering substrate 8 is used, it is possible to cut the covering substrate 8 at the peripheral edge of the adhesive sealing layer 9. The covering substrate 8 may be cut simultaneously with the moisture-proof substrate 1 at the position of the division line 16. Cutting the integrated substrate can be facilitated if the moisture-proof substrate 1 and the covering substrate 8 are made of the same material (e.g., glass).

It is possible in this way to obtain an organic EL element such as that shown in FIGS. 1A and 1B.

### [Organic EL Element]

In the organic EL element shown in FIGS. 1A and 1B, the organic electroluminescent laminate 7 is formed on the surface of the resin film 2, as described above. The moisture-proof substrate 1 and the resin film 2 are optically transparent light-transmissive substrates and the first electrode 13 of the organic electroluminescent laminate 7 is an optically transparent light-transmissive electrode. Normally, the first electrode 13 is an anode and the second electrode 15 is a cathode, but this may be reversed. The second electrode 15 is a light-reflecting electrode. In such a case, the light generated in the organic layer 14 can be reflected by the second electrode 15 to be guided outward. Alternatively, a light-transmissive electrode may be used as the second electrode 15 and a reflective layer may be formed on the opposite side of the second electrode 15 from the organic layer 14.

In the present embodiment, the organic electroluminescent laminate 7 is formed on the surface of the resin film 2 embedded in the moisture-proof substrate 1 and the light generated in the organic layer 14 enters into the moisture-proof substrate 1 via the first electrode 13 and the resin film 2 and then travels outward through the moisture-proof substrate 1. The light passes through the resin film 2 and thus, the light is released outward in a greater amount. The light generated in the light-emitting layer reaches the substrate directly or indirectly by reflection. When the difference in refractive index at the interface is large, the light cannot be released in a great amount due to total reflection. When the first electrode 13 is formed directly on the surface of the moisture-proof substrate 1, the difference in refractive index becomes larger, leading to reduction of the amount of the light released. Accordingly in the present embodiment, the substrate used is a composite substrate 3 of a moisture-proof substrate 1 and a resin film 2 and a resin film 2 having a refractive index close to that of the first electrode 13 is placed to the light output side of the first electrode 13. It is thus possible to reduce the difference in refractive index between the first electrode 13 and the composite substrate 3 and to increase the light-outcoupling efficiency by suppressing total reflection.

Also in the present embodiment, a light-outcoupling structure 4 is formed at the interface between the moisture-proof substrate 1 and the resin film 2. The light-outcoupling structure 4 is formed by roughening a face to be the interface between the moisture-proof substrate 1 and the resin film 2. When the fine surface unevenness of the moisture-proof substrate 1 is formed by surface roughening, the light is scattered by the fine surface unevenness to different directions, and the light traveling in the direction of total reflection is redirected to other direction, thus increasing the amount of the light emitted. Alternatively when the light-outcoupling structure 4 is formed by incorporation of air bubbles, the air bubbles reduce the refractive index, leading to increase of the light output.

Another light-outcoupling structure may be formed additionally at the interface between the resin film 2 and the moisture-proof substrate 1. For example, it is possible to form a light-outcoupling structure by forming a light-scattering layer containing light-scattering particles on the moisture-proof substrate 1-sided surface of the resin film 2. Yet alternatively, the light-outcoupling structure may be formed as a layer different from the moisture-proof substrate 1 and the resin film 2.

In the organic EL element, the light is generated by combining holes and electrons in the organic layer 14 when voltage is applied between the first electrode 13 and the second electrode 15. Therefore, it is needed to install electrode terminals electrically connected respectively to the first electrode 13 and the second electrode 15 in the region outside the covered region. The electrode terminals are terminals for electrical connection to external electrodes. In the embodiment shown in FIGS. 1A and 1B, electrode layers 6 are formed so as to be in contact with the electrode extensions 11 and 12 extending from respective electrodes and the electrode layers 6 extend outward from the covered region, forming electrode terminals.

In the present embodiment, the first electrode 13, the first electrode extension 11 and the second electrode extension 12 are made of the same electroconductive layer 10. The central region of the electroconductive layer 10 constitutes the first electrode 13, while the end regions of the electroconductive layer 10 constitute the first electrode extension 11 and the second electrode extension 12. The first electrode extension 11 is formed, as the electroconductive layer 10 constituting the first electrode 13 is extended onto the end surface of the resin film 2. The first electrode extension 11 is in contact with the first electrode layer 6a on the end surface of the resin film 2. In the present embodiment, the first electrode layer 6a is formed on the surface of the first electrode extension 11. The first electrode layer 6a is formed outside the covered region, as it extends toward the end region of the moisture-proof substrate 1, and thus serves as an electrode terminal corresponding to the first electrode 13. Alternatively, the second electrode extension 12 is formed, as part of the electroconductive layer 10 for forming the first electrode 13 is separated from the first electrode 13 and extends onto the end surface of the resin film 2. The second electrode extension 12 is in contact with the second electrode layer 6b on the end surface of the resin film 2. In the present embodiment, the second electrode layer 6b is formed on the surface of the second electrode extension 12. The second electrode layer 6b is formed outside the covered region, as it extends toward the end region of the moisture-proof substrate 1, and thus serves as the electrode terminal corresponding to the second electrode 15.

In the present embodiment, the organic electroluminescent laminate 7 is enclosed and isolated from the external space, as a covering substrate 8 larger than the resin film 2 is adhered to the organic electroluminescent laminate 7-sided surface of the composite substrate 3. As the resin film 2 is smaller than the covered region in a plan view, it is unexposed outward and blocked from the external space. The surface of the resin film 2 on the side opposite to the organic electroluminescent laminate 7 is covered with the moisture-proof substrate 1 and isolated from the external space. The resin film 2 is fitted into the recess 5 of the moisture-proof substrate 1 so that the side wall (peripheral end face) is not exposed out of the surface and the side wall of the resin film 2 is isolated from the external space, as it is surrounded by the moisture-proof substrate 1. All the region of the organic electroluminescent laminate 7-sided surface of the resin film 2 is present in the covered region in a plan view, is covered entirely, and isolated from the external space. Thus, the resin film 2 is not exposed, as a whole, to the external space. It is possible for that reason to suppress water penetration and thus deterioration of the organic EL element.

In the organic EL element, the organic electroluminescent laminate 7 is covered by the covering substrate 8 that is adhered to the composite substrate 3 with the adhesive sealing layer 9. If the composite substrate 3 has a resin film 2, there arises a problem of water penetration via the resin film 2. When the resin film 2 is exposed to the external space, there is a concern that water may penetrate into the resin film 2 via the externally exposed region and the penetrated water reaches the organic electroluminescent laminate 7 through the resin film 2. Exposure of the organic electroluminescent laminate 7 to water may results in degradation of the element. Thus in the organic EL element in the present embodiment, as the resin film 2 is embedded in the moisture-proof substrate 1 and the organic electroluminescent laminate 7 is covered so as to be enclosed by a covering substrate 8 larger than the resin film 2. Thus, the resin film 2 is not externally exposed anymore and protected from penetration of water from outside. The adhesive sealing layer 9 can be formed at least in the end region (peripheral region) of the covering substrate 8. It is thus possible to suppress external exposure of the resin film 2.

As the resin film 2 is embedded in the moisture-proof substrate 1, it is possible to make the substrate thinner, compared to that the resin film 2 is formed on the entire surface of the moisture-proof substrate 1. It is thus possible to reduce the thickness of the organic EL element and form a thinner element easily. It is also possible to produce an organic EL element efficiently by forming a composite substrate 3 having a resin film 2 embedded therein.

The organic EL element in the embodiment shown in FIGS. 1A and 1B is not limited to that prepared by the production method described above. For example, the composite substrate 3 may be prepared by forming a resin film 2 by pouring and solidifying a fluidal resin composition in the recesses 5 of the moisture-proof substrate 1. Also in this case, it is possible to place the resin film 2 to the light output side of the organic electroluminescent laminate 7 and make the resin film 2 unexposed to the external space and thus, to raise the light-outcoupling efficiency and suppress water penetration. However, in order to obtain a substrate having favorable light-outcoupling efficiency, it is preferable to form a composite substrate 3 by adhering a molded resin film 2 onto a moisture-proof substrate 1.

The electrode layer 6 in the organic EL element may also serve as the electroconductive layer 10. In this case, the electrode layer 6 is an optically transparent light-transmissive layer. In the embodiment in which the electrode layer 6 serves also as the electroconductive layer 10, it is possible to produce an organic EL element according to the production method described above, using a resin film 2 not carrying the electroconductive layer 10 previously formed. In the electrode layer-forming step, the electrode layer 6 (electroconductive layer 10) is formed on the surface of the resin film 2 in the pattern of forming a first electrode 13 and an electrode extension. In this case, the electrode layer 6 is formed in the central region of the resin film 2, as it extends from the covered region to the external space across the boundary region between the resin film 2 and the moisture-proof substrate 1. Also in this case, it is possible to place the resin film 2 on the light output side of the organic electroluminescent laminate 7 and make the resin film 2 unexposed to the external space and thus, to raise the light-outcoupling efficiency and suppress water penetration. However, for improvement of the electrical conductivity of the electrode layer 6 and for assurance of transparency of the electroconductive layer 10, it is preferable to form the electrode layer 6 and the electroconductive layer 10 respectively of different materials.

Also in the organic EL element in the embodiment of FIGS. 1A and 1B, an electroconductive layer 10 is formed in the region of the resin film 2 in a plan view and the electroconductive layer 10 is not formed on the surface of the moisture-proof substrate 1. However, the electroconductive layer 10 may be formed on the surface of the moisture-proof substrate 1. Such an organic EL element can be prepared according to the production method described above, using a resin film 2 not carrying an electroconductive layer 10 previously formed. And in the electrode layer-forming step, an electroconductive layer 10 may be formed on the surface of the resin film 2, as the electroconductive layer 10 and the electrode layer 6 are formed sequentially in that order or in the reverse order in the pattern of forming the first electrode 13 and the electrode extension. Also in this case, it is possible to place the resin film 2 to the light output side and make the resin film 2 unexposed to the external space and thus, to raise the light-outcoupling efficiency and suppress water penetration.

### Embodiment 2

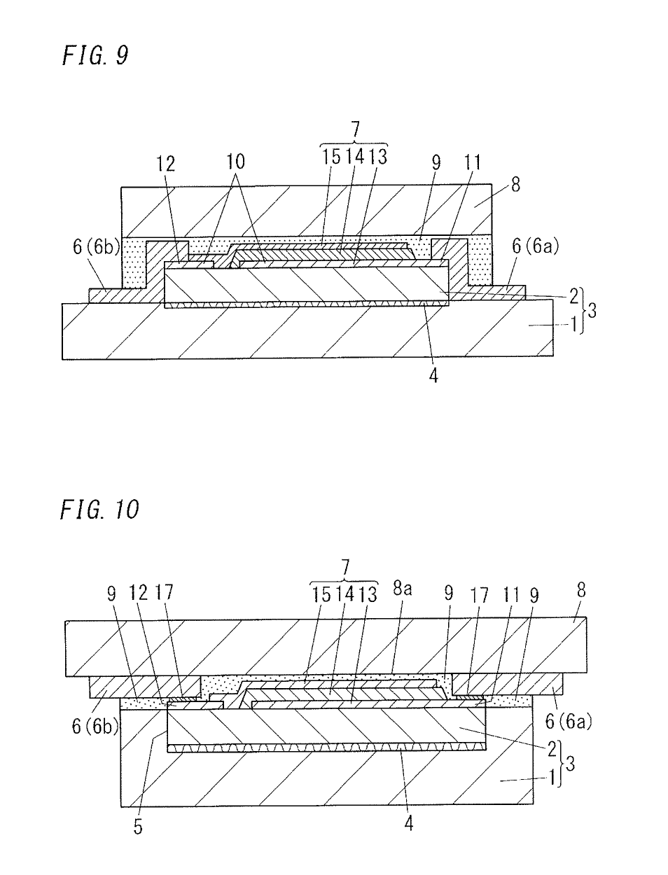

FIG. 9 shows an embodiment of the organic electroluminescent element (organic EL element). The organic EL element has a configuration similar to that shown in FIGS. 1A and 1B, except that the structure of the composite substrate 3 is different. Specifically, a composite substrate 3 including a moisture-proof substrate 1 and a resin film 2 is used as the substrate on which an organic electroluminescent laminate 7 is formed. The light-outcoupling structure 4 is formed at the interface between the moisture-proof substrate 1 and the resin film 2. An organic electroluminescent laminate 7 having a first electrode 13, an organic layer 14 and a second electrode 15 in that order are formed on the surface of the resin film 2 of the composite substrate 3. The organic electroluminescent laminate 7 is covered with a covering substrate 8 adhered to the composite substrate 3 with an adhesive sealing layer 9. The covering substrate 8 is larger than the resin film 2 in a plan view. In FIG. 9, the end region for the first electrode layer Ga is shown in the right side of the figure and the end region for the second electrode layer 6b in the left side of the figure, to make the element configuration more recognizable.

In contrast to the embodiment shown in FIGS. 1A and 1B, there is no recess 5 formed on the moisture-proof substrate 1 and the resin film 2 is not embedded in the moisture-proof substrate 1 in the embodiment shown in FIG. 9. A light-outcoupling structure 4 is formed by surface roughening of the moisture-proof substrate 1. A resin film 2 is formed on the roughened surface of the moisture-proof substrate 1. Thus, the resin film 2 is formed on the light-outcoupling structure 4. Also in the embodiment of FIG. 9, it is possible to raise the light-outcoupling efficiency by forming a light-outcoupling structure 4 at the interface between the moisture-proof substrate 1 and the resin film 2.

### [Preparation of Organic EL Element]

A method for preparing an organic EL element shown in FIG. 9 will be described below.

The organic EL element in the present embodiment is prepared in a process including a roughening step, a composite substrate-forming step, an electroluminescent laminate-forming step and a covering step. The roughening step is a step of roughening the surface of the moisture-proof substrate 1. The composite substrate-forming step is a step of forming a composite substrate 3 by providing a resin film 2 on the surface of the moisture-proof substrate 1. The electroluminescent laminate-forming step is a step of forming an organic electroluminescent laminate 7 on the surface of the composite substrate 3. The covering step is a step of covering the organic electroluminescent laminate 7 with a covering substrate 8 larger than the resin film 2 in a plan view.

The roughening step can be carried out in a manner similar to the method of roughening described in FIGS. 3A to 3G and 4A to 4F. As there is no need for forming a recess 5 in the present embodiment, it is possible to provide a protective member 41 directly on the surface of the moisture-proof substrate 1 without forming a recess and roughen the surface by blasting with particles 42. The roughening may be conducted all over the surface of the moisture-proof substrate 1 or only over the region where the resin film 2 is provided. In FIG. 9, the surface of the moisture-proof substrate 1 is roughened partially in the central region and the resin film 2 is provided on the roughened face. As described above, surface-roughening only of the region where the resin film 2 is formed gives a light-outcoupling structure 4 efficiently. In addition, a favorably stabilized layer can be formed without cleavage of the layers provided on the surface of the moisture-proof substrate 1 such as electrode layers 6.

In the embodiment of FIG. 9, the composite substrate 3 can be formed by adhering a resin film 2 to the surface-roughened region of the moisture-proof substrate 1. The moisture-proof substrate 1 and the resin film 2 may be adhered to each other (forming a composite substrate 3) and the electrode layers 6 is formed according to methods similar to those described in FIGS. 5 and 6. In addition, the electroluminescent laminate can be formed and covered according to a method similar to that described in FIGS. 7A to 7F.

### [Organic EL Element]

In the organic EL element of FIG. 9, it is possible to increase the light-outcoupling efficiency, similarly to the organic EL element of FIGS. 1A and 1B because the substrate is a composite substrate 3 of moisture-proof substrate 1 and resin film 2. It is also possible to increase the light-outcoupling efficiency further owing to a light-outcoupling structure 4 formed by surface roughening of the surface of the moisture-proof substrate 1.

In the present embodiment, the organic electroluminescent laminate 7 is blocked and covered from external space, as a covering substrate 8 larger than the resin film 2 is adhered to the organic electroluminescent laminate 7-sided surface of the composite substrate 3. Since the resin film 2 is smaller than the covered region in a plan view, the resin film 2 is not exposed outward and blocked from the external space. That is, the surface of the resin film 2 opposite to the organic electroluminescent laminate 7 is covered with the moisture-proof substrate 1 and isolated from the external space. The side wall of the resin film 2 is covered with the electrode layers 6 and the adhesive sealing layer 9, and isolated from the external space. The surface of the resin film 2 on the side of the organic electroluminescent laminate 7 is sealed entirely, in a plan view, inside the covered region and thus isolated from the external space. Thus, the resin film 2 is not exposed outward entirely. It is thus possible to suppress water penetration and suppress degradation of the organic EL element.

The embodiment shown in FIG. 9, in which there is no recess 5 formed on the moisture-proof substrate 1, is advantageous in that it is possible to produce the organic EL element more easily than the embodiment of FIGS. 1A and 1B. However for more effective prevention of water penetration, the organic EL element shown in FIGS. 1A and 1B in which the resin film 2 is fitted into the recess 5 is more advantageous. In the organic EL element of FIGS. 1A and 1B, the surface of the resin film 2 and the surface of the moisture-proof substrate 1 are positioned at the same level, and such a configuration is advantageous in that the breakage of electrode layer 6 caused by the difference in level of the surfaces seldom occurs and the connection reliability is heightened. In addition, the organic EL element of FIGS. 1A and 1B is suited for reduction of thickness because in the organic EL element, the resin film 2 is embedded.

### Embodiment 3

FIG. 10 shows an embodiment of the organic electroluminescent element (organic EL element). The organic EL element has a configuration similar to that shown in FIGS. 1A and 1B, except that the structure of covering and the structure of the electrode layers 6 are different. Specifically, a composite substrate 3 includes a moisture-proof substrate 1 and a resin film 2, and is used as the substrate on which an organic electroluminescent laminate 7 is formed. The resin film 2 is embedded in the moisture-proof substrate 1. A light-outcoupling structure 4 is formed at the interface between the moisture-proof substrate 1 and the resin film 2. The organic electroluminescent laminate 7 having a first electrode 13, an organic layer 14 and a second electrode 15 in that order is formed on the surface of the resin film 2 of the composite substrate 3. The organic electroluminescent laminate 7 is covered with a covering substrate 8 adhered to the composite substrate 3 with an adhesive sealing layer 9. The covering substrate 8 is larger than the resin film 2 in a plan view. In FIG. 10, the end region for the first electrode layer 6a is shown in the right side of the figure and the end region for the second electrode layer 6b in the left side of the figure, to make the element configuration more recognizable.

In the embodiment of FIG. 10, in contrast to the embodiment of FIGS. 1A and 1B, the electrode layers 6 are formed on the composite substrate 3-sided surface of the covering substrate 8 and there is an adhesive sealing layer 9 formed between the electrode layer 6 and the composite substrate 3. The electrode layers 6 are formed, as they extend inward from outside the covered region to inside. The electrode layers 6 include a first electrode layer 6a electrically connected to the first electrode 13 and a second electrode layer 6b electrically connected to the second electrode 15. The electrode layers 6 can serve as electrode terminals for connection to external electric wirings. Electrode-connecting layers 17 each connecting electrically the electrode extension with the electrode layer 6 are formed between the electrode layer 6 and the first electrode extension 11 and also between the electrode layer 6 and the second electrode extension 12. The electrode-connecting layers 17 improve the current flow between the electrode layer 6 and each electrode extension.

In addition, in the embodiment of FIG. 10, the covering substrate 8 is formed larger than the composite substrate 3 (moisture-proof substrate 1), in a plan view. Thus, the electrode layers 6 formed on the end surface of the covering substrate 8 are exposed outward. The electrode layers 6 are exposed on the light extraction-sided surface of the covering substrate 8. In addition, the covering substrate 8 is adhered to the moisture-proof substrate 1 (composite substrate 3) directly in the end region without intervention of the resin film 2.

### [Preparation of Organic EL Element]

A method for preparing an organic EL element shown in FIG. 10 will be described below.

The organic EL element in the present embodiment is prepared in a process including a recess-forming step, a roughening step, a composite substrate-forming step, an electroluminescent laminate-forming step and a covering step. The recess-forming step is a step of forming a recess 5 by digging the surface of the moisture-proof substrate 1. The roughening step is a step of roughening the surface of the moisture-proof substrate 1. The composite substrate-forming step is a step of forming a composite substrate 3 by forming a resin film 2 on the surface of the moisture-proof substrate 1. The electroluminescent laminate-forming step is a step of forming an organic electroluminescent laminate 7 on the surface of the composite substrate 3. The covering step is a step of covering the organic electroluminescent laminate 7 with a covering substrate 8 larger than the resin film 2 in a plan view.

In the present embodiment, the recess-forming step and the roughening step may be carried out simultaneously or separately, similarly to the embodiment of FIGS. 1A and 1B. When the recess-forming step and the roughening step are carried out simultaneously, production is much simpler. When the recess-forming step and the roughening step are carried out separately, it is possible to form a light-outcoupling structure 4 higher in light-outcoupling efficiency by roughening. In FIG. 10, the moisture-proof substrate 1 has a recess 5 and a resin film 2 is fitted into the recess 5. It is thus possible to suppress water penetration effectively.

In the present embodiment, the preparing method further includes an electrode layer-forming step. The electrode layer-forming step in the present embodiment is a step of forming electrode layers 6 (first electrode layer 6a and second electrode layer 6b) on the surface of the covering substrate 8 before the covering step so that they are electrically connected to the electrodes (first electrode 13 and second electrode 15) of the organic electroluminescent laminate 7 in the covering step.

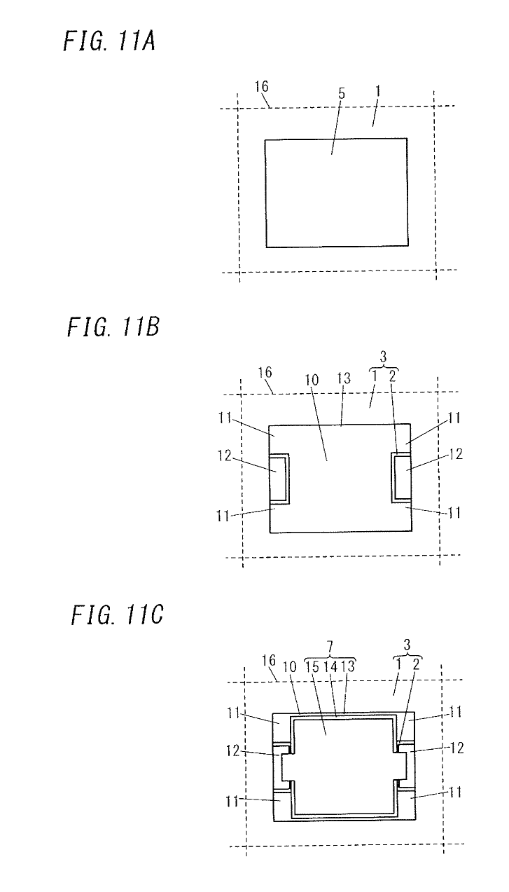

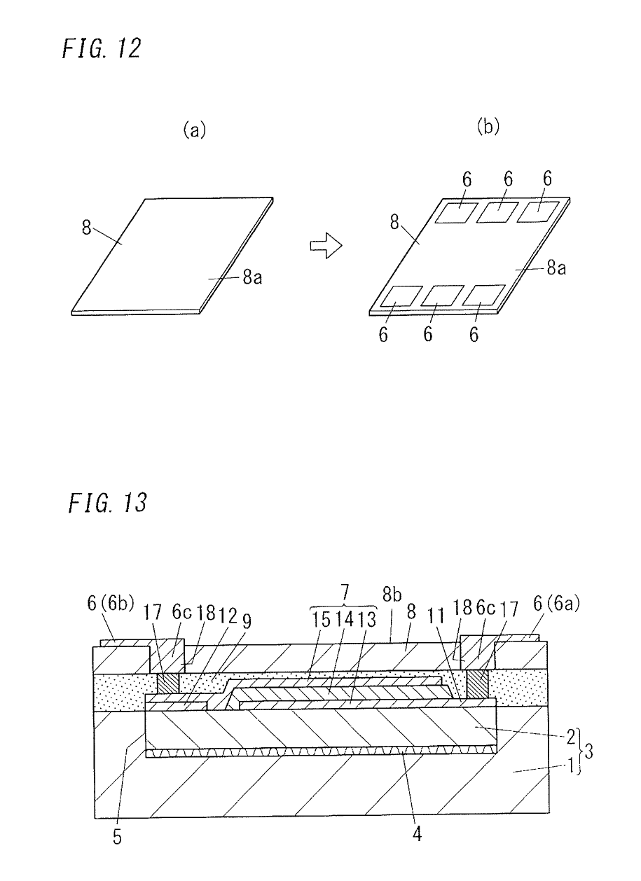

FIGS. 11A to 11C and FIG. 12 show an embodiment of a method for preparing the organic EL element shown in FIG. 10. A composite substrate 3 is first prepared also in this embodiment. The composite substrate 3 can be prepared according to a method similar to that described in the embodiment of FIGS. 1A and 1B. Specifically as shown in FIG. 11A, a recess 5 having a roughened face is formed on a moisture-proof substrate 1 in the recess-forming step and the roughening step and, as shown in FIG. 11B, a composite substrate 3 having a resin film 2 inserted into the recess 5 of the moisture-proof substrate 1 is prepared in the composite substrate-forming step. The bottom face of the recess 5 thus formed may be roughened after the recess is formed according to a method similar to that shown in FIGS. 3A to 3G or FIGS. 4A to 4F. An electroconductive layer 10 may be previously formed on the surface of the resin film 2.

In the present embodiment, an organic electroluminescent laminate 7 is formed by lamination on the composite substrate shown in FIG. 11B. The organic electroluminescent laminate 7 can be formed according to a method similar to that shown in FIGS. 1A and 1B. In this way, an organic electroluminescent laminate 7 is formed on the surface of the composite substrate 3, as shown in FIG. 11C.

FIG. 12 shows how electrode layers 6 are formed. In the present embodiment, the electrode layers 6 are formed on the surface of a covering substrate 8 before covering. The electrode layers 6 are formed on the surface 8a of the covering substrate 8 on the side of the organic electroluminescent laminate 7. The electrode layers 6 can be formed on the surface of a flat surface covering substrate 8, as shown in FIG. 12 (a), in a proper pattern, as shown in FIG. 12 (b). The electrode layers 6 can be formed according to a method similar to that shown in FIGS. 1A and 1B. For example, it can be formed by a printing process. The electrode layers 6 are then formed separately at the positions respectively corresponding to the electrode extensions at the end region of the covering substrate 8, so that the electrode layers 6 is electrically connected to the organic electroluminescent laminate 7 when the covering substrate 8 is adhered to the composite substrate 3 in the covering step. A first electrode layer 6a is formed from the electrode layer 6 at the position corresponding to the first electrode extension 11a and a second electrode layer 6b is formed from the electrode layer 6 at the position corresponding to the second electrode extension 12. Although electrode layers 6 are formed on the covering substrate 8 for a single element as shown in FIGS. 12 (a) and (b), a covering substrate 8 having a size suitable for multiple elements (e.g., 4 elements) may be used, as described in the embodiment of FIGS. 1A and 1B. It is thus possible to cover multiple elements simultaneously.

A sealant adhesive is applied to a region larger than the resin film 2 in composite substrate 3 and the covering substrate 8 carrying an electrode layer 6 on the surface is adhered to the composite substrate 3 with the adhesive sealing layer 9, with its electrode layer 6-sided surface facing the composite substrate 3. For assurance of electrical conductivity, the surface of the electrode layer 6 and the electrode extension are placed at positions facing each other and adhered in the absence of the adhesive in the region. Preferably, a conductive material for preparation of the electrode-connecting layer 17 is provided on the surface of each electrode extension (region facing electrode layers 6). In the absence of the material for electrode-connecting layer 17, the sealant adhesive may intrude into the region between the electrode layer 6 and the electrode extension, possibly leading to insufficient or reduced electrical conductivity. However, it is possible in the presence of the material for electrode-connecting layer 17 to assure higher electrical conductivity.

The material for use as the electrode-connecting layer 17 may be an electroconductive paste. Such an electroconductive paste is fluidal and thus can be applied on the surface of the electrode extension easily. In addition, the electroconductive paste, when hardened, assures favorable current flow between the electrode extension and the electrode layer 6. The electroconductive paste for use may be a silver paste. For example, a low-out gas low-temperature hardening silver paste can be used preferably. Such silver pastes are commercially available, for example from Henkel under the name of QMI. The paste may be hardened simultaneously with the sealant.

Before application of the sealant adhesive, the electroconductive paste may be coated in advance, the composite substrate 3 and the covering substrate 8, may be adhered to each other by hardening the electroconductive paste, and the sealant may be filled into the space between the composite substrate 3 and the covering substrate 8 by a side-fill method. A method of coating a resin on the peripheral region of the substrate under reduced-pressure atmosphere and making the resin penetrate into the element under vacuum may be used as the side-fill method. It is possible by the method to facilitate release of out gas when the electroconductive paste is hardened and to prevent contact of the mask for printing to the element, void generation in the sealant and others. The sealing device for use may be a sealing device for use in production of liquid crystal displays.

It is possible in this way to produce the organic EL element in the embodiment of FIG. 10.

In the present embodiment, the electrode layer 6 is not formed across the boundary region between the moisture-proof substrate 1 and the resin film 2, as in the embodiment of FIGS. 1A and 1B, and it is thus possible to form the electrode layer 6 without disconnection. It is thus possible to increase electrical conductivity. However, because the electrode terminals (external electrodes) of the electrode layer 6 are formed on the side of the light-emitting face (moisture-proof substrate 1 side of covering substrate 8), electrical connection may become difficult and thus, the embodiment of FIGS. 1A and 1B is advantageous from the point of electrical connection.

### Embodiment 4

FIG. 13 shows an embodiment of the organic electroluminescent element (organic EL element). The organic EL element has a configuration similar to that shown in FIGS. 1A and 1B, except that the structure of covering and the structure of the electrode layers 6 are different. Specifically, a composite substrate 3 including a moisture-proof substrate 1 and a resin film 2 is used as the substrate on which an organic electroluminescent laminate 7 is formed. The resin film 2 is embedded in the moisture-proof substrate 1. A light-outcoupling structure 4 is formed at the interface between the moisture-proof substrate 1 and the resin film 2. The organic electroluminescent laminate 7 having a first electrode 13, an organic layer 14 and a second electrode 15 in that order is formed on the surface of the resin film 2 of the composite substrate 3. The organic electroluminescent laminate 7 is covered with a covering substrate 8 adhered to the composite substrate 3 with an adhesive sealing layer 9. The covering substrate 8 is larger than the resin film 2 in a plan view. In FIG. 13, the end region for the first electrode layer 6a is shown in the right side of the figure and the end region for the second electrode layer 6b in the left side of the figure, to make the element configuration more recognizable.

In contrast to the embodiments of FIGS. 1A and 1B and FIG. 10, the electrode layers 6 are formed on the surface 8b of the covering substrate 8 opposite to the composite substrate 3, as they are filled in through-holes 18 formed in the covering substrate 8 in the embodiment of FIG. 13. The electrode layers 6 include a first electrode layer 6a electrically connected to the first electrode 13 and a second electrode layer 6b electrically connected to the second electrode 13. The electrode layers 6 can serve as electrode terminals for connection to external electric wirings. An electrode-connecting layer 17 electrically connecting each electrode extension with the electrode layer 6 is formed between the electrode layer 6 (penetration electrode 6c) formed in the through-hole 18 and the first electrode extension 11 and between the electrode layers 6 and the second electrode extension 12. When the electrode-connecting layer 17 is formed, current flow between the penetration electrode 6c (electrode layer 6) and each electrode extension increases.

Also in the embodiment of FIG. 13, the covering substrate 8 is formed in the size similar, in a plan view, to that of the composite substrate 3 (moisture-proof substrate 1). The electrode layer 6 formed on the external surface of the covering substrate 8 extends to the end region. The electrode layer 6 is exposed on the surface of the covering substrate 8 opposite to the light output side. Thus, the electrode layer 6 can be electrically connected with external devices more easily than that in the embodiment of FIG. 10. The covering substrate 8 is adhered to the moisture-proof substrate 1 (composite substrate 3) directly without the resin film 2 in the end region.

### [Preparation of Organic EL Element]

The production method for the organic EL element shown in FIG. 13 will be described below.

The organic EL element in the present embodiment is prepared in a process including a recess-forming step, a roughening step, a composite substrate-forming step, an electroluminescent laminate-forming step and a covering step. The recess-forming step is a step of forming a recess 5 by digging the surface of the moisture-proof substrate 1. The roughening step is a step of roughening the surface of the moisture-proof substrate 1. The composite substrate-forming step is a step of forming a composite substrate 3 by forming a resin film 2 on the surface of the moisture-proof substrate 1. The electroluminescent laminate-forming step is a step of forming an organic electroluminescent laminate 7 on the surface of the composite substrate 3. The covering step is a step of covering the organic electroluminescent laminate 7 with a covering substrate 8 larger than the resin film 2 in a plan view.

In the present embodiment, the recess-forming step and the roughening step may be carried out simultaneously or separately, similarly to the embodiment of FIGS. 1A and 1B. When the recess-forming step and the roughening step are carried out simultaneously, production is much simpler. When the recess-forming step and the roughening step are carried out separately, it is possible to form a light-outcoupling structure 4 higher in light-outcoupling efficiency by roughening. In FIG. 13, the moisture-proof substrate 1 has a recess 5 and a resin film 2 is fitted into the recess 5. It is thus possible to suppress water penetration effectively.

In the present embodiment, the preparing method further includes an electrode layer-forming step. The electrode layer-forming step in the present embodiment is a step of forming electrode layers 6 (first electrode layer 6a and second electrode layer 6b) on the surface of the covering substrate 8 before the covering step so as to be electrically connected to the electrodes (first electrode 13 and second electrode 15) of the organic electroluminescent laminate 7 in the covering step.

Also in the present embodiment, while the organic electroluminescent laminate 7 is formed after the composite substrate 3 is first prepared, the composite substrate 3 is prepared and the organic electroluminescent laminate 7 is laminated according to a method similar to that shown in the embodiment of FIG. 10. Specifically, a recess 5 are formed in the moisture-proof substrate 1 as shown in FIG. 11A, a resin film 2 is inserted into the recess 5 as shown in FIG. 11B, and an organic electroluminescent laminate 7 is formed on the surface of the composite substrate 3 as shown in FIG. 11C. The specific method may be the same as that shown in the embodiment of FIGS. 1A and 1B. The method may include a roughening step additionally after formation of the recess 5.

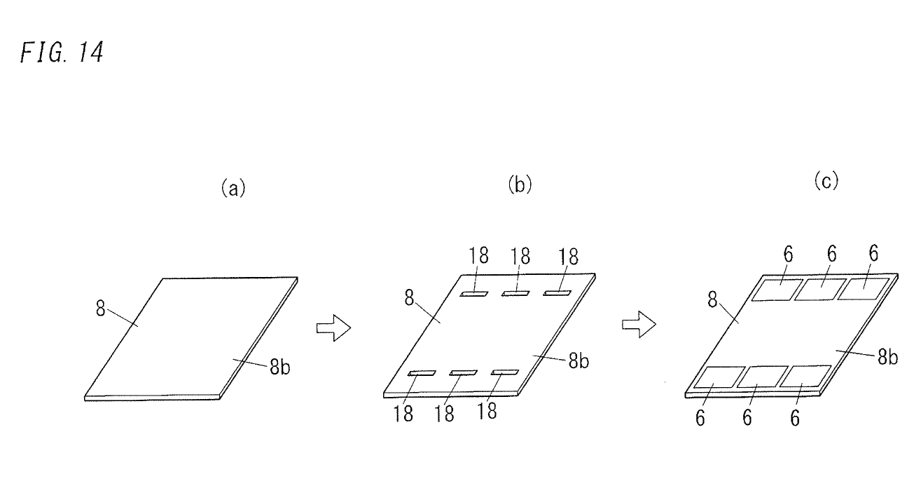

FIG. 14 shows the process for preparation of the electrode layers 6. In the present embodiment, the electrode layers 6 are formed on the surface of the covering substrate 8 and in the through-holes 18 before covering. The face of the covering substrate 8 where the electrode layers 6 are formed is opposite to the face where they are formed shown in the embodiment of FIG. 10. Specifically, while the electrode layers 6 are formed on the organic electroluminescent laminate 7-sided face 8a in the embodiment of FIG. 10, the electrode layers 6 are formed on the face 8b opposite to the organic electroluminescent laminate 7 in the embodiment of FIG. 13. In preparation of the electrode layers 6, first as shown in FIG. 14 (a), through-holes 18 are formed on a flat-surfaced covering substrate 8 in a suitable pattern as shown in FIG. 14 (b). In this embodiment, a plurality of rectangular through-holes 18 are formed at the positions corresponding to the first electrode extensions 11 and the second electrode extensions 12.

The through-holes 18 can be formed according to a method similar to that for preparation of the recesses 5 on the moisture-proof substrate 1. For example, the through-holes 18 can be formed by sand blasting process. It is possible by the sand blasting process to form the through-holes 18 easily. The through-holes 18 may be formed, for example, by etching. Alternatively, the through-holes 18 may be formed by cutting. In preparation of the through-holes 18, the through-holes 18 are formed separately at the position corresponding to respective electrode extensions, so that the electrode layer 6 is electrically connected to the electrodes of the organic electroluminescent laminate 7 when the covering substrate 8 is adhered to the composite substrate 3 in the covering step.

In the present embodiment, the covering substrate 8 for use is preferably a thin material. When the covering substrate 8 is thin, the through-holes 18 are prepared easily. Also when the covering substrate 8 is thin, it is easy to fill the through-holes 18 with the electrode layers 6. An example of the thin covering substrate 8 is thin plate glass. The thickness of the covering substrate 8 may be 10 to 2000 μm, but is not limited thereto. The plate glass for use may be, for example, a thin sheet glass (manufactured by Nippon Electric Glass Co., Ltd.: 50 μm).

Then as shown in FIG. 14 (c), the electrode layers 6 are formed in the regions containing the through-holes 18 in a suitable pattern. The electrode layers 6 may be formed according to a method similar to that in the embodiment of FIGS. 1A and 1B. Specifically, they can be formed, for example, by printing process. When the covering substrate 8 is thin, the electrode layers 6 can be filled into the through-holes 18 by printing. Of course, the electrode layers 6 may be formed by a method other than the printing method. Especially when the covering substrate 8 is thick, it may become difficult to fill the through-holes 18 with electrode layers 6 by printing and thus, the electrode layers 6 may be formed, for example, by applying.

The electrode layer 6 formed in the through-hole 18 at the position corresponding to the first electrode extension 11 serves as a first electrode layer 6a, and the electrode layer 6 formed in the through-hole 18 at the position corresponding to the second electrode extension 12 serves as a second electrode layer 6b. Although through-holes 18 and electrode layers 6 are formed on a covering substrate 8 for a single element in FIG. 14 (a) to (c), a covering substrate 8 in the size for multiple elements (e.g., 4 elements) may be used, as described in the embodiment of FIGS. 1A and 1B. It is thus possible to cover multiple elements simultaneously.

A sealant adhesive is applied to a region larger than the resin film 2 in the composite substrate 3 and the covering substrate 8 carrying through-holes 18 filled with electrode layers 6 is adhered to the composite substrate 3 with the adhesive sealing layer 9 so that the opposite side (face where penetration electrodes 6c are exposed) of the covering substrate 8 from the electrode layers 6 faces the composite substrate 3. For assurance of electrical conductivity, the surface of penetration electrodes 6c (electrode layers 6) and the electrode extensions are arranged so as to face each other, and adhered in the absence of the adhesive in the region. Preferably, a conductive material for the electrode-connecting layer 17 is provided on the surface of each electrode extension (region facing electrode layers 6). In absence of the material for electrode-connecting layer 17, the sealant adhesive may intrude into the region between the electrode layer 6 and the electrode extension, possibly leading to insufficient or reduced electrical conductivity. However, it is possible in the presence of the material for electrode-connecting layer 17 to assure higher electrical conductivity.

The material for the electrode-connecting layer 17 may be an electroconductive paste. The electroconductive paste for use may be a paste similar to that described in the embodiment of FIG. 10. The paste may be hardened simultaneously with the sealant.

Before application of the sealant adhesive, the electroconductive paste may be coated in advance, and then hardened to bond the composite substrate 3 and the covering substrate 8. Thereafter, the sealant may be filled into the space between the composite substrate 3 and the covering substrate 8 by a side-fill method. The side-fill method may be a method of coating a resin on the peripheral region of the substrate under reduced-pressure atmosphere and making it penetrate into the element under vacuum. It is possible by the method to facilitate release of out gas when the electroconductive paste is hardened and to prevent contact of the mask for printing with the element, void generation in the sealant and others. The sealing device used in this step may be a device for producing liquid crystal displays.

It is possible in this way to produce the organic EL element in the embodiment of FIG. 13.

In the present embodiment, the electrode layer 6 is not formed across the boundary region between the moisture-proof substrate 1 and the resin film 2, as in the embodiment of FIGS. 1A and 1B, and it is possible to form the electrode layer 6 without disconnection. It is thus possible to increase electrical conductivity. Since the electrode extensions are formed on the external face of the covering substrate 8 and thus, there is no need for extension of the electrode extensions to the side, it is possible to make the non-light-emitting region in the peripheral region smaller and obtain an organic EL element having a higher proportion of light-emitting area. However, this process may include an additional number of steps such as through-hole 18-forming step and thus, the process in the embodiment of FIGS. 1A and 1B may be more advantageous in productivity.

### Embodiment 5

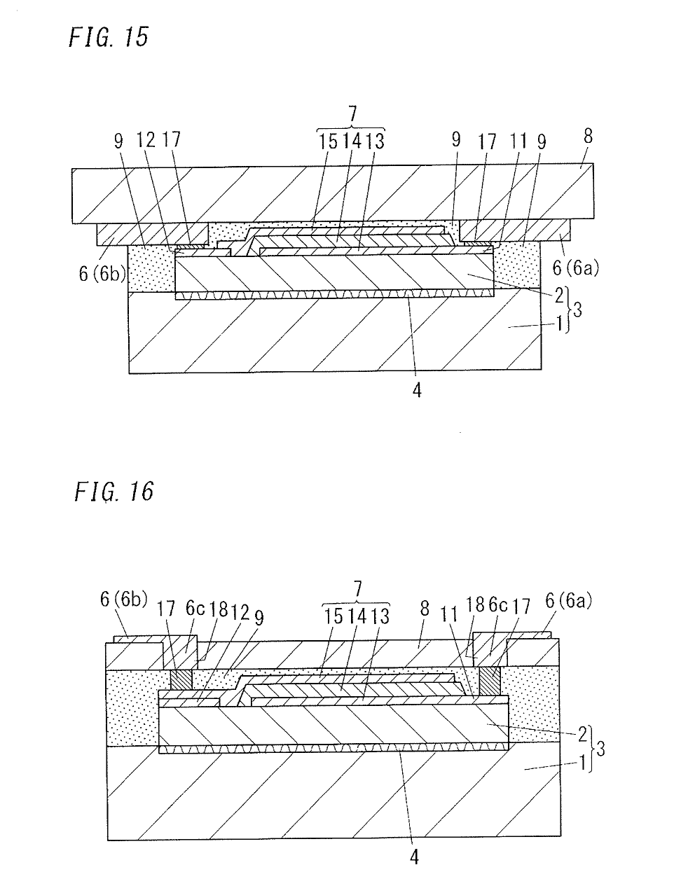

FIG. 15 shows an embodiment of the organic electroluminescent element (organic EL element). The organic EL element has a configuration similar to that shown in FIG. 10, except for the structure of the composite substrate 3. Specifically, a composite substrate 3 including a moisture-proof substrate 1 and a resin film 2 is used as the substrate on which an organic electroluminescent laminate 7 is formed. A light-outcoupling structure 4 is formed at the interface between the moisture-proof substrate 1 and the resin film 2. The organic electroluminescent laminate 7 having a first electrode 13, an organic layer 14 and a second electrode 15 in that order is formed on the surface of the resin film 2 of the composite substrate 3. The organic electroluminescent laminate 7 is covered with a covering substrate 8 that is adhered to the composite substrate 3 with an adhesive sealing layer 9. The covering substrate 8 is larger than the resin film 2 in a plan view. Electrode layers 6 are formed on the surface of the covering substrate 8. Electrode-connecting layers 17 each electrically connecting the electrode extension with the electrode layer 6 are formed between the electrode layer 6 and the first electrode extension 11 and also between the electrode layer 6 and the second electrode extension 12.

In contrast to the embodiment shown in FIG. 10, there is no recess 5 formed on the moisture-proof substrate 1 and the resin film 2 is not embedded in the moisture-proof substrate 1 in the embodiment shown in FIG. 15. The light-outcoupling structure 4 is formed by surface roughening of the moisture-proof substrate 1. A resin film 2 is provided on the roughened surface of the moisture-proof substrate 1. Thus, the resin film 2 is provided on the light-outcoupling structure 4. Also in the embodiment of FIG. 15, it is possible to raise the light-outcoupling efficiency by forming the light-outcoupling structure 4 at the interface between the moisture-proof substrate 1 and the resin film 2.

The composite substrate 3 for use may be a substrate similar to that described in FIG. 9. The covering substrate 8 and the electrode layer 6 for use may be those similar to those described in FIG. 10. The organic EL element of FIG. 15 may be considered to be a modified embodiment in combination of the composite substrate 3 shown in FIG. 9 and the covering substrate 8 shown in FIG. 10. The materials and the configuration may be similar to those shown in FIGS. 9 and 10. The composite substrate 3 and the structure on the surface of it in the organic EL element is produced similarly to the production of organic EL element in FIG. 9, while the covering substrate 8 and the structure on the surface of it therein similarly to the production of the organic EL element in FIG. 10.

### Embodiment 6

FIG. 16 shows an embodiment of the organic electroluminescent element (organic EL element). The organic EL element has a configuration similar to that shown in FIG. 13, except for the structure of the composite substrate 3. Specifically, a composite substrate 3 including a moisture-proof substrate 1 and a resin film 2 is used as the substrate on which an organic electroluminescent laminate 7 is formed. A light-outcoupling structure 4 is formed at the interface between the moisture-proof substrate 1 and the resin film 2. The organic electroluminescent laminate 7 having a first electrode 13, an organic layer 14 and a second electrode 15 in that order is formed on the surface of the resin film 2 of the composite substrate 3. The organic electroluminescent laminate 7 is covered with a covering substrate 8 that is adhered to the composite substrate 3 with an adhesive sealing layer 9. The covering substrate 8 is larger than the resin film 2 in a plan view. Electrode layers 6 are formed on the surface of the covering substrate 8. Electrode-connecting layers 17 each electrically connecting the electrode extension with the electrode layer 6 are formed between the electrode layer 6 and the first electrode extension 11 and also between the electrode layer 6 and the second electrode extension 12.

In contrast to the embodiment shown in FIG. 13, there is no recess 5 formed on the moisture-proof substrate 1 and the resin film 2 is not embedded in the moisture-proof substrate 1 in the embodiment shown in FIG. 16. The light-outcoupling structure 4 is formed by surface roughening of the moisture-proof substrate 1. The resin film 2 is formed on the roughened surface of the moisture-proof substrate 1. Thus, the resin film 2 is formed on the light-outcoupling structure 4. Also in the embodiment of FIG. 16, it is possible to raise the light-outcoupling efficiency by forming the light-outcoupling structure 4 at the interface between the moisture-proof substrate 1 and the resin film 2.

The composite substrate 3 for use may be a substrate similar to that described in FIG. 9. The covering substrate 8 and the electrode layer 6 for use may be those similar to those described in FIG. 13. The organic EL element of FIG. 16 may be considered to be a modified embodiment in combination of the composite substrate 3 shown in FIG. 9 and the covering substrate 8 shown in FIG. 13. The materials and the configuration may be similar to those shown in FIGS. 9 and 13. The composite substrate 3 and the structure on the surface of it in the organic EL element is produced similarly to the production of organic EL element in FIG. 9, while the covering substrate 8 and the structure on the surface of it therein similarly to the production of the organic EL element in FIG. 13.

### <Composite Substrate Structure>

As described above, the composite substrate 3 can be used preferably for production of organic EL elements, but the composite substrate 3 can also be used as a substrate for sealing organic electric elements other than organic EL elements. Examples of the organic electric elements include organic semiconductor elements, organic solar cells, organic display devices (displays) and the like. In production of these elements, a composite substrate 3 having a resin film 2 fitted into the recess 5 of the moisture-proof substrate 1 or a composite substrate 3 additionally having an electrode layer 6 on the surface (electrode-carrying composite substrate) may be used as the composite substrate structure.

FIG. 6 (e) and FIG. 7C show examples of the electrode-carrying composite substrates. The electrode-carrying composite substrate is a composite substrate 3, which includes a moisture-proof substrate 1 and a resin film 2, having electrode layers 6 formed on the surface of the resin film 2 side. The resin film 2 is embedded in the moisture-proof substrate 1. The electrode layer 6 is formed across the boundary region between the resin film 2 and the moisture-proof substrate 1.

In the electrode-carrying composite substrate, electroconductive layers 10 may be formed on the surface of the resin film 2, as shown in FIG. 6 (e). The electrode layer 6 may also serve as the electroconductive layer 10, as described above. There may be no electroconductive layer 10 formed.

It is possible to produce an organic electric element by using the electrode-carrying composite substrate, forming an organic laminate for the organic electric element on the surface of a resin film 2, and covering the laminate with a covering substrate 8 larger than the resin film 2 by a method similar to that for organic EL elements. Also in this case, it is possible to obtain an organic electric element that is resistant to water penetration via the resin film 2. For example, it may be used when an organic laminated film is desirably formed on a resin film 2 of a particular material.

The electrode-carrying composite substrate is prepared according to the method for producing the composite substrate 3 in production of the organic EL element above. Specifically, as shown in FIGS. 2 to 6 and FIGS. 7A to 7C, the electrode-carrying composite substrate can be prepared in a process including a recess-forming step, a roughening step, a composite substrate-forming step and an electrode layer-forming step. The recess-forming step is a step of forming a recess 5 in the surface of the moisture-proof substrate 1 by digging. The roughening step is a step of roughening the surface of the moisture-proof substrate 1. If the roughening of the surface of the moisture-proof substrate 1 is not required in the desired organic electric element, this roughening step may be eliminated. The composite substrate-forming step is a step of forming a composite substrate 3 by forming a resin film 2 on the surface of the moisture-proof substrate 1. When the moisture-proof substrate 1 has a recess 5, it is possible to form a composite substrate 3 by fitting a resin film 2 into the recess 5. The electrode layer-forming step is a step of forming an electrode layer 6 on the surface of the composite substrate 3 across the boundary region between the resin film 2 and the moisture-proof substrate 1. The materials and the methods may be similar to those used in production of the organic EL element above. It is possible in this way to produce easily a composite substrate 3 for organic electric elements that are resistant to water penetration via the resin film 2.

In a preferable embodiment of the composite substrate structure, a covering substrate 8 larger than the resin film 2 in a plan view is adhered to a moisture-proof substrate 1. In this case, it is possible to obtain an organic electric element in which an organic laminate is formed on the surface of the resin film 2 in the composite substrate 3 including a moisture-proof substrate 1 and a resin film 2. When the moisture-proof substrate 1 has a recess 5, the resin film 2 is embedded in the moisture-proof substrate 1 and the organic laminated film is covered with a covering substrate 8 larger than the resin film 2 in a plan view in the organic electric element. Thus, the organic electric element is highly resistant to water penetration. The electrode layer 6 in the organic electric element may be formed on the surface of the composite substrate 3, on the surface of the covering substrate 8 or in the through-hole 18 of the covering substrate 8.

### DESCRIPTION OF REFERENCE NUMERALS

1 Moisture-proof substrate
2 Resin film
3 Composite substrate
4 Light-outcoupling structure
5 Recess
6 Electrode layer
7 Organic electroluminescent laminate
8 Covering substrate
9 Adhesive sealing layer
10 Electroconductive layer
11 First electrode extension
12 Second electrode extension
13 First electrode
14 Organic layer
15 Second electrode
16 Division line
17 Electrode-connecting layer
18 Through-hole
40 Surface layer
41 Protective member
42 Particles

1. A method of preparing an organic electroluminescent element, comprising
a roughening step of roughening a surface of a moisture-proof substrate,
a composite substrate-forming step of placing a resin film on the roughened surface of the moisture-proof substrate to form a composite substrate,
an electroluminescent laminate-forming step of forming an organic electroluminescent laminate on a surface of the composite substrate, and
a covering step of covering the organic electroluminescent laminate with a covering substrate that is larger than the resin film in a plan view.

2. The method of preparing an organic electroluminescent element according to claim 1, further comprising
a recess-forming step of forming a recess in the surface of the moisture-proof substrate by digging,
the composite substrate-forming step being carried out by fitting the resin film into the recess to form the composite substrate.

3. The method of preparing an organic electroluminescent element according to claim 1, wherein
the roughening step is carried out by providing the surface of the moisture-proof substrate with a protective member and roughening the surface.

4. The method of preparing an organic electroluminescent element according to claim 1, wherein
in the roughening step, the surface is roughened by making particles collide with the surface of the moisture-proof substrate.

5. The method of preparing an organic electroluminescent element according to claim 2, wherein
the recess-forming step is carried out by making particles collide with the surface of the moisture-proof substrate to form the recess.

6. The method of preparing an organic electroluminescent element according to claim 2, wherein
the roughening step and the recess-forming step are carried out simultaneously.

7. The method of preparing an organic electroluminescent element according to claim 1, further comprising
an electrode layer-forming step of:
forming an electrode layer on the surface of the composite substrate after the composite substrate-forming step so that the electrode layer extends across a boundary between the resin film and the moisture-proof substrate; or
forming an electrode layer on a surface of the covering substrate before the covering step so that the electrode layer is to be electrically connected to an electrode of the organic electroluminescent laminate in the covering step.

8. The method of preparing an organic electroluminescent element according to claim 7, wherein
the electrode layer is formed by printing.

9. An organic electroluminescent element, comprising:
a composite substrate including a moisture-proof substrate and a resin film, the moisture-proof substrate having a roughened surface, and the resin film being placed on the roughened surface of the moisture-proof substrate;
a covering substrate being larger than the resin film in a plan view; and
an organic electroluminescent laminate formed on a surface of the resin film, the organic electroluminescent laminate being covered with the covering substrate.

10. The organic electroluminescent element according to claim 9, wherein
the resin film is embedded in the moisture-proof substrate.

11. The organic electroluminescent element according to claim 9, further comprising
an electrode layer,
the electrode layer being formed on a surface of the composite substrate so as to extend across a boundary between the moisture-proof substrate and the resin film, or
the electrode layer being formed on a surface of the covering substrate.

12. The organic electroluminescent element according to claim 10, further comprising
an electrode layer,
the electrode layer being formed on a surface of the composite substrate so as to extend across a boundary between the moisture-proof substrate and the resin film, or
the electrode layer being formed on a surface of the covering substrate.

13. The method of preparing an organic electroluminescent element according to claim 3, wherein
in the roughening step, the surface is roughened by making particles collide with the surface of the moisture-proof substrate.

14. The method of preparing an organic electroluminescent element according to claim 5, wherein
the roughening step and the recess-forming step are carried out simultaneously.

15. The method of preparing an organic electroluminescent element according to claim 2, further comprising
an electrode layer-forming step of:
forming an electrode layer on the surface of the composite substrate after the composite substrate-forming step so that the electrode layer extends across a boundary between the resin film and the moisture-proof substrate; or
forming an electrode layer on a surface of the covering substrate before the covering step so that the electrode layer is to be electrically connected to an electrode of the organic electroluminescent laminate in the covering step.

16. The method of preparing an organic electroluminescent element according to claim 3, further comprising
an electrode layer-forming step of:
forming an electrode layer on the surface of the composite substrate after the composite substrate-forming step so that the electrode layer extends across a boundary between the resin film and the moisture-proof substrate; or
forming an electrode layer on a surface of the covering substrate before the covering step so that the electrode layer is to be electrically connected to an electrode of the organic electroluminescent laminate in the covering step.

17. The method of preparing an organic electroluminescent element according to claim 5, further comprising
an electrode layer-forming step of:
forming an electrode layer on the surface of the composite substrate after the composite substrate-forming step so that the electrode layer extends across a boundary between the resin film and the moisture-proof substrate; or
forming an electrode layer on a surface of the covering substrate before the covering step so that the electrode layer is to be electrically connected to an electrode of the organic electroluminescent laminate in the covering step.

18. The method of preparing an organic electroluminescent element according to claim 15, wherein
the electrode layer is formed by printing.

19. The method of preparing an organic electroluminescent element according to claim 16, wherein
the electrode layer is formed by printing.

20. The method of preparing an organic electroluminescent element according to claim 17, wherein
the electrode layer is formed by printing.
